(19) United States
(12) Patent Application Publication
(10) Pub. No.: US 2026/0088073 A1
(43) Pub. Date: Mar. 26, 2026

(54) SEMICONDUCTOR MEMORY DEVICE

(71) Applicant: KIOXIA CORPORATION, Tokyo (JP)

(72) Inventors: Viktoria Diana SCHLYKOW, Kamakura Kanagawa (JP); Reika TANAKA, Yokohama Kanagawa (JP); Masamichi SUZUKI, Koto Tokyo (JP); Manabu TEZURA, Arakawa Tokyo (JP)

(73) Assignee: KIOXIA CORPORATION, Tokyo (JP)

(21) Appl. No.: 19/077,139

(22) Filed: Mar. 12, 2025

(30) Foreign Application Priority Data
Sep. 20, 2024 (JP) 2024-163631

(51) Int. Cl. G11C 11/22

(52) U.S. Cl. CPC G11C 11/2275; G11C 11/221; G11C 11/223

(57) ABSTRACT

A semiconductor memory device of an embodiment includes a memory cell including a semiconductor layer, a gate electrode layer containing a ferroelectric, and a first wiring and a second wiring connected to the semiconductor layer, and a control circuit. The control circuit executes a first write operation of applying a first voltage with a first polarity to the memory cell, and executes a second write operation of applying a second voltage having a smaller absolute value than the first voltage with the first polarity to the memory cell. The control circuit executes a first operation to the memory cell before the second write operation to the memory cell. The first operation applies a voltage having a larger absolute value than the second voltage with the first polarity and applies a voltage having a larger absolute value than the second voltage with a polarity opposite to the first polarity.

### CROSS-REFERENCE TO RELATED APPLICATION

This application is based upon and claims the benefit of priority from Japanese Patent Application No. 2024-163631, filed on Sep. 20, 2024, the entire contents of which are incorporated herein by reference.

### FIELD

Embodiments described herein relate generally to a semiconductor memory device.

### BACKGROUND

There is a nonvolatile semiconductor memory device using a ferroelectric for memory cells.

### BRIEF DESCRIPTION OF THE DRAWINGS

FIG. 1 is a block diagram of a memory system including a semiconductor memory device of a first embodiment;

FIG. 2 is an equivalent circuit diagram of a part of a memory cell array of the semiconductor memory device of the first embodiment;

FIG. 3 is a schematic cross-sectional view including a memory cell of the semiconductor memory device of the first embodiment;

FIG. 4 is an explanatory diagram of the memory cell of the semiconductor memory device of the first embodiment;

FIG. 5 is a timing chart describing a control method of the semiconductor memory device of the first embodiment;

FIG. 6 is a timing chart describing a control method of the semiconductor memory device of the first embodiment;

FIG. 7 is an explanatory diagram of the function and effect of the semiconductor memory device of the first embodiment;

FIG. 8 is an explanatory diagram of a memory cell of a modification of the semiconductor memory device of the first embodiment;

FIG. 9 is a timing chart describing a control method of a modification of the semiconductor memory device of the first embodiment;

FIG. 10 is a timing chart describing a control method of a modification of the semiconductor memory device of the first embodiment;

FIG. 11 is an explanatory diagram of the function and effect of a modification of the semiconductor memory device of the first embodiment;

FIG. 12 is a block diagram of a memory system including a semiconductor memory device of a second embodiment;

FIG. 13 is a timing chart describing a control method of the semiconductor memory device of the second embodiment;

FIG. 14 is a timing chart describing a control method of the semiconductor memory device of the second embodiment;

FIG. 15 is a timing chart describing a control method of a modification of the semiconductor memory device of the second embodiment;

FIG. 16 is a timing chart describing a control method of a modification of the semiconductor memory device of the second embodiment;

FIG. 17 is a block diagram of a memory system including a semiconductor memory device of a third embodiment;

FIG. 18 is an equivalent circuit diagram of memory blocks of the semiconductor memory device of the third embodiment;

FIG. 19 is an equivalent circuit diagram of a part of a memory cell array of the semiconductor memory device of the third embodiment;

FIG. 20 is a schematic cross-sectional view of a part of the memory cell array of the semiconductor memory device of the third embodiment;

FIG. 21 is a schematic cross-sectional view of a part of the memory cell array of the semiconductor memory device of the third embodiment;

FIG. 22 is a block diagram of a memory system including a semiconductor memory device of a fourth embodiment;

FIG. 23 is a timing chart describing a control method of the semiconductor memory device of the fourth embodiment;

FIG. 24 is a timing chart describing a control method of a modification of the semiconductor memory device of the fourth embodiment;

FIG. 25 is a block diagram of a memory system including a semiconductor memory device of a fifth embodiment;

FIG. 26 is an equivalent circuit diagram of a part of a memory cell array of the semiconductor memory device of the fifth embodiment;

FIG. 27 is a schematic cross-sectional view including a memory cell of the semiconductor memory device of the fifth embodiment; and

FIG. 28 is a block diagram of a memory system including a semiconductor memory device of a sixth embodiment.

### DETAILED DESCRIPTION

A semiconductor memory device of an embodiment includes: a memory cell including a semiconductor layer, a gate electrode layer, and a gate insulating layer containing a ferroelectric and provided between the semiconductor layer and the gate electrode layer; a first wiring and a second wiring electrically connected to the semiconductor layer; and a control circuit configured to control the memory cell, wherein the control circuit is configured to execute a first write operation to the memory cell, and in the first write operation, a first voltage pulse having a first voltage with a first polarity and a first pulse width is applied between the gate electrode layer and at least one of the first wiring and the second wiring, the control circuit is configured to execute an erase operation to the memory cell, and in the erase operation, a second voltage pulse having a second voltage with a second polarity opposite to the first polarity and a second pulse width is applied between the gate electrode layer and at least one of the first wiring and the second wiring, the control circuit is configured to execute a second write operation to the memory cell, and in the second write operation, a third voltage pulse having a third voltage with the first polarity having a smaller absolute value than an absolute value of the first voltage and a third pulse width is applied between the gate electrode layer and at least one of the first wiring and the second wiring, and the control circuit is configured to execute a first operation to the memory cell before the second write operation, the first operation is consecutive with the second write operation, and in the first operation, a fourth voltage pulse having a fourth voltage with the first polarity having a larger absolute value than the absolute value of the third voltage and a fourth pulse width and a fifth voltage pulse having a fifth voltage with the second polarity having a larger absolute value than the absolute value of the third voltage and a fifth pulse width are applied between the gate electrode layer and at least one of the first wiring and the second wiring, and the fifth voltage pulse is applied consecutively after the fourth voltage pulse is applied.

Hereinafter, embodiments of the disclosure will be described with reference to the drawings. In the following description, the same or similar members and the like are denoted by the same reference numerals, and the description of the members and the like once described is appropriately omitted. For components with reference numerals followed by numbers or letters for differentiation, if there is no need to distinguish between the components for the purpose of explanation, reference numerals may be used with the numbers or letters at the end omitted.

The qualitative analysis and quantitative analysis of the chemical composition of members constituting the semiconductor memory device in this specification can be performed by, for example, secondary ion mass spectroscopy (SIMS), energy dispersive X-ray spectroscopy (EDX), electron energy loss spectroscopy (EELS), X-ray photoelectron spectroscopy (XPS), or the like. In measurement of the thickness of each member forming the semiconductor memory device, a distance between members, and the like, for example, a transmission electron microscope (TEM) can be used. In identification of the space group of the crystal of members constituting the semiconductor memory device, for example, scanning transmission electron microscope (STEM), X-ray diffraction (XRD), electron beam diffraction (EBD), X-ray photoelectron spectroscopy (XPS), or synchrotron radiation X-ray absorption fine structure (XAFS) can be used.

### First Embodiment

A semiconductor memory device of a first embodiment includes: a memory cell including a semiconductor layer, a gate electrode layer, and a gate insulating layer containing a ferroelectric and provided between the semiconductor layer and the gate electrode layer; a first wiring and a second wiring electrically connected to the semiconductor layer; and a control circuit configured to control the memory cell. The control circuit is capable of executing a first write operation to the memory cell. The first write operation is to apply a first voltage pulse having a first voltage with a first polarity and a first pulse width between the gate electrode layer and at least one of the first wiring and the second wiring. The control circuit is capable of executing an erase operation to the memory cell. The erase operation is to apply a second voltage pulse having a second voltage with a second polarity opposite to the first polarity and a second pulse width between the gate electrode layer and at least one of the first wiring and the second wiring. The control circuit is capable of executing a second write operation to the memory cell. The second write operation is to apply a third voltage pulse having a third voltage with the first polarity having a smaller absolute value than an absolute value of the first voltage and a third pulse width between the gate electrode layer and at least one of the first wiring and the second wiring. The control circuit is capable of executing a first operation to the memory cell before the second write operation, the first operation being consecutive with the second write operation. The first operation is to apply a fourth voltage pulse having a fourth voltage with the first polarity having a larger absolute value than the absolute value of the third voltage and a fourth pulse width and apply a fifth voltage pulse having a fifth voltage with the second polarity having a larger absolute value than the absolute value of the third voltage and a fifth pulse width between the gate electrode layer and at least one of the first wiring and the second wiring, the applying of the fifth voltage pulse being consecutive with the applying of the fourth voltage pulse.

The semiconductor memory device of the first embodiment is a ferroelectric memory using a ferroelectric. The semiconductor memory device of the first embodiment includes a two-dimensional NOR memory. The semiconductor memory device of the first embodiment uses, as the memory cell, a field effect transistor containing a ferroelectric in a gate insulating layer. The semiconductor memory device of the first embodiment is a multi-level memory in which one memory cell can hold three or more levels.

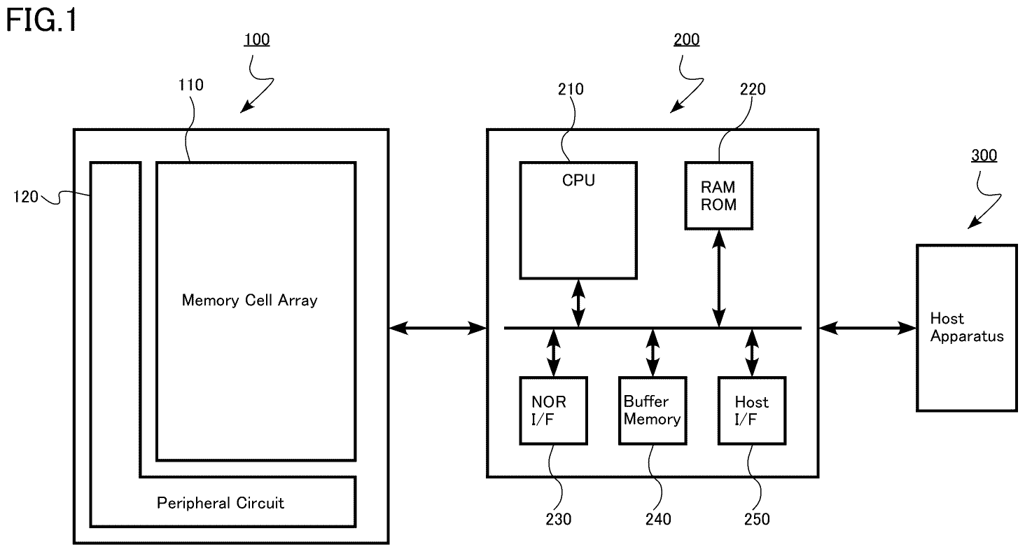

FIG. 1 is a block diagram of a memory system including a semiconductor memory device of a first embodiment. The memory system of the first embodiment includes, for example, a two-dimensional NOR memory 100, a controller 200, and a host apparatus 300. The semiconductor memory device of the first embodiment includes, for example, the two-dimensional NOR memory 100 and the controller 200.

The two-dimensional NOR memory 100 is, for example, a two-dimensional NOR memory chip. The controller 200 is, for example, a controller chip. The two-dimensional NOR memory 100 and the controller 200 may be provided in the same semiconductor chip, for example.

The host apparatus 300 is, for example, a personal computer.

As illustrated in FIG. 1, the two-dimensional NOR memory 100 includes a memory cell array 110 and a peripheral circuit 120.

The peripheral circuit 120 is provided around the memory cell array 110. The peripheral circuit 120 has, for example, a function of controlling the operation of the memory cell array 110 according to an instruction received from the controller 200.

The controller 200 controls the two-dimensional NOR memory 100. The controller 200 accesses the two-dimensional NOR memory 100 in response to an instruction received from the host apparatus 300.

The peripheral circuit 120 of the two-dimensional NOR memory 100 and the controller 200 control, for example, writing of data to a memory cell included in the memory cell array 110, reading of data from the memory cell, or erasing data in the memory cell. The peripheral circuit 120 of the two-dimensional NOR memory 100 and the controller 200 are examples of the control circuit of the first embodiment.

As illustrated in FIG. 1, the controller 200 includes a processor 210 (CPU), a built-in memory 220 (RAM, ROM), a NOR interface circuit 230, a buffer memory 240, and a host interface circuit 250.

The processor 210 controls the overall operation of the controller 200. The processor 210 has a function of executing various processes for managing the two-dimensional NOR memory 100.

The built-in memory 220 is, for example, a semiconductor memory. The built-in memory 220 is used, for example, as a work area for the processor. The built-in memory 220 stores, for example, firmware for managing the two-dimensional NOR memory 100 and various management tables.

The NOR interface circuit 230 is connected to the two-dimensional NOR memory 100 via a NOR bus. The NOR interface circuit 230 has a function of controlling communication with the two-dimensional NOR memory 100. The buffer memory 240 has, for example, a function of temporarily storing data written into memory cells or data read from memory cells.

The host interface circuit 250 is connected to the host apparatus 300 via a host bus. The host interface circuit 250 transmits, for example, an instruction received from the host apparatus 300 to the processor 210. The host interface circuit 250 transmits, for example, data received from the host apparatus 300 to the buffer memory 240. The host interface circuit 250 transmits, for example, data in the buffer memory 240 to the host apparatus 300 in response to an instruction from the processor 210.

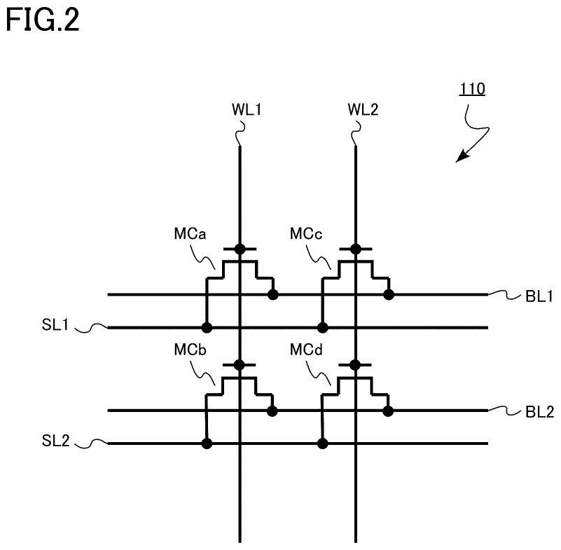

FIG. 2 is an equivalent circuit diagram of a part of a memory cell array of the semiconductor memory device of the first embodiment. FIG. 2 is an equivalent circuit diagram of a part of the memory cell array 110 of the two-dimensional NOR memory 100.

As illustrated in FIG. 2, the memory cell array 110 includes a plurality of memory cells MC, a plurality of source lines SL, a plurality of bit lines BL, and a plurality of word lines WL. The plurality of memory cells MC include a memory cell MCa, a memory cell MCb, a memory cell MCc, and a memory cell MCd. The plurality of source lines SL includes a first source line SL1 and a second source line SL2. The plurality of bit lines BL includes a first bit line BL1 and a second bit line BL2. The plurality of word lines WL include a first word line WL1 and a second word line WL2.

The plurality of word lines WL are arranged in parallel so as to be spaced from each other. The plurality of bit lines BL cross the word lines WL, for example. The plurality of bit lines BL are arranged in parallel so as to be spaced from each other. The plurality of source lines SL cross the word lines WL, for example. The plurality of source lines SL are arranged in parallel so as to be spaced from each other.

By selecting one source line SL, one bit line BL, and one word line WL, one memory cell MC can be selected. The word line WL is a gate electrode of a transistor constituting the memory cell MC. The transistor of the memory cell MC is a field effect transistor whose operation is controlled by a voltage applied to its gate electrode.

The two-dimensional NOR memory 100 is configured to allow random access to the plurality of memory cells MC included in the memory cell array 110.

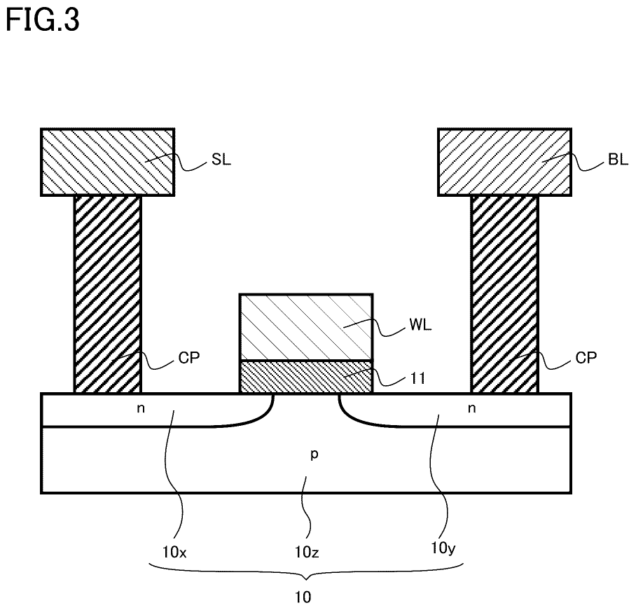

FIG. 3 is a schematic cross-sectional view including a memory cell of the semiconductor memory device of the first embodiment.

As illustrated in FIG. 3, the memory cell MC includes a semiconductor layer 10, a word line WL, a gate insulating layer 11, and contact plugs CP. The semiconductor layer 10 includes a source region 10x, a drain region 10y, and a channel region 10z. The source line SL and the bit line BL are connected to the memory cell MC.

The word line WL is an example of the gate electrode layer. The source line SL is an example of the first wiring. The bit line BL is an example of the second wiring.

The semiconductor layer 10 is, for example, single crystal silicon. The source region 10x and the drain region 10y are, for example, n-type semiconductors. The channel region 10z is, for example, a p-type semiconductor. The source line SL is electrically connected to the source region 10x by using the contact plug CP. The bit line BL is electrically connected to the drain region 10y by using the contact plug CP.

The word line WL is a conductor. The word line WL is, for example, a metal. The contact plug CP is a conductor. The contact plug CP is, for example, a metal.

The gate insulating layer 11 contains a ferroelectric. The gate insulating layer 11 is, for example, a ferroelectric layer.

The gate insulating layer 11 contains, for example, at least one element selected from the group consisting of hafnium (Hf) and zirconium (Zr), and oxygen.

The gate insulating layer 11 is, for example, polycrystalline. The gate insulating layer 11 contains, for example, a crystal having one space group selected from the group consisting of a space group Pca21 (space group number 29), a space group R3 (space group number 146), a space group R3m (space group number 160), and Pmn21 (space group number 31). An oxide of hafnium (Hf) or zirconium (Zr) having a space group Pca21 (space group number 29), space group R3 (space group number 146), space group R3m (space group number 160), or Pmn21 (space group number 31) is a ferroelectric.

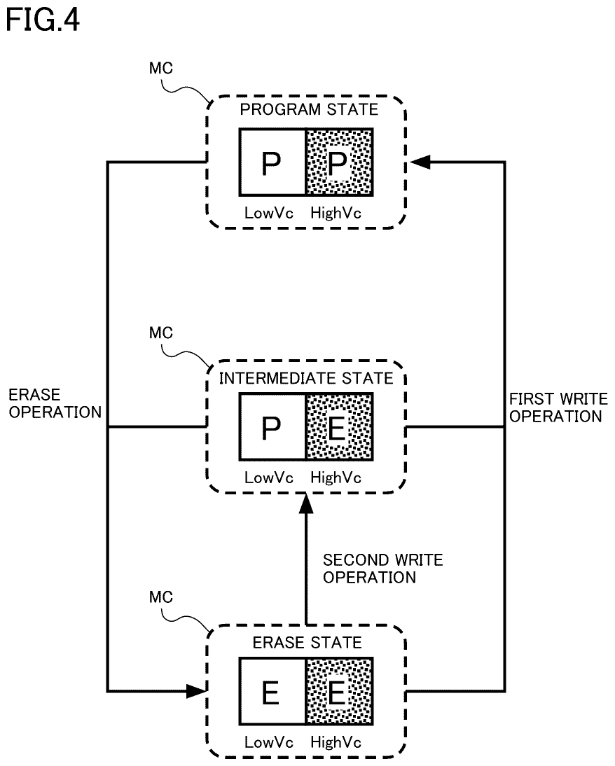

FIG. 4 is an explanatory diagram of the memory cell of the semiconductor memory device of the first embodiment. FIG. 4 is an explanatory diagram of a possible level of the memory cell MC.

As illustrated in FIG. 4, the memory cell MC can take three states of an erase state, a program state, and an intermediate state. The transistor of the memory cell MC can have a threshold voltage corresponding to each state. Since the memory cell MC can take three states, the two-dimensional NOR memory 100 functions as a multi-level memory.

As illustrated in FIG. 4, it is considered that there are two polarization domains having different coercive voltages (Vc) in the ferroelectric of the memory cell MC. The polarization domains are a low coercive voltage domain (Low Vc domain) having a low coercive voltage and a high coercive voltage domain (High Vc domain) having a high coercive voltage. It is assumed that each polarization domain can independently take an erase state and a program state. The polarization direction of the polarization domain is different between the erase state and the program state.

When the memory cell MC is in the erase state, the low coercive voltage domain is in the erase state (E) and the high coercive voltage domain is in the erase state (E). When the memory cell MC is in the intermediate state, the low coercive voltage domain is in the program state (P) and the high coercive voltage domain is in the erase state (E). When the memory cell MC is in the program state, the low coercive voltage domain is in the program state (P) and the high coercive voltage domain is in the program state (P).

For example, by performing the first write operation on the memory cell MC in the erase state, polarization inversion occurs in the low coercive voltage domain and the high coercive voltage domain, and the low coercive voltage domain and the high coercive voltage domain are in the program state (P). As a result, the memory cell MC transitions from the erase state to the program state.

For example, by performing the second write operation on the memory cell MC in the erase state, domain polarization inversion occurs in only the low coercive voltage domain, the low coercive voltage domain is in the program state (P), and the high coercive voltage domain remains in the erase state (E). As a result, the memory cell MC transitions from the erase state to the intermediate state.

For example, by performing the erase operation on the memory cell MC in the program state, polarization inversion occurs in the low coercive voltage domain and the high coercive voltage domain, and the low coercive voltage domain and the high coercive voltage domain are in the erase state (E). As a result, the memory cell MC transitions from the program state to the erase state.

For example, by performing the erase operation on the memory cell MC in the intermediate state, polarization inversion of the low coercive voltage domain occurs, and the low coercive voltage domain is in the erase state (E). As a result, the memory cell MC transitions from the intermediate state to the erase state.

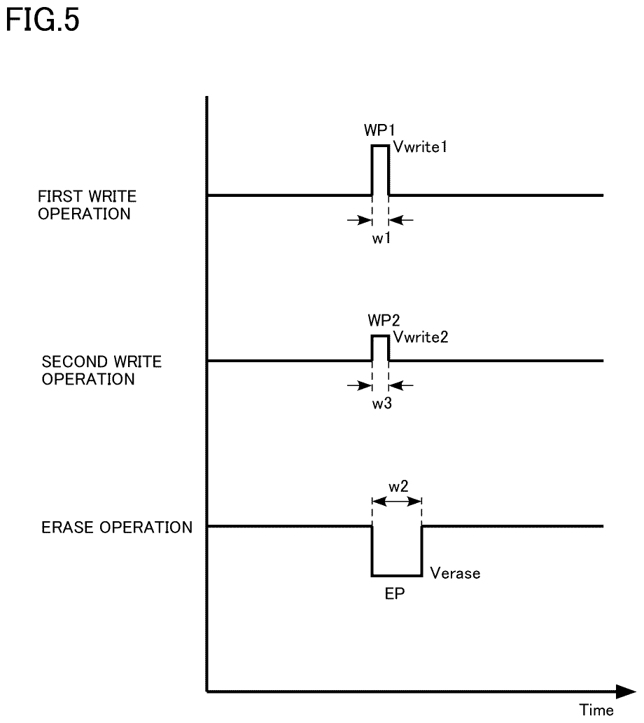

FIG. 5 is a timing chart describing a control method of the semiconductor memory device of the first embodiment. FIG. 5 illustrates a voltage pulse applied to the memory cell MC included in the memory cell array 110. FIG. 5 illustrates a voltage pulse applied to the memory cell MC during the first write operation, the second write operation, and the erase operation.

The peripheral circuit 120 of the two-dimensional NOR memory 100 and the controller 200 control, for example, the plurality of memory cells MC in the memory cell array 110. For example, the peripheral circuit 120 and the controller 200 control the memory cells MCa to MCd.

The peripheral circuit 120 and the controller 200 are capable of executing the first write operation, the second write operation, and the erase operation to any one memory cell MC selected from the memory cells MCa to MCd, for example. The peripheral circuit 120 and the controller 200 can read data stored in any one memory cell MC selected from the memory cells MCa to MCd, for example.

FIG. 5 illustrates a case where the first write operation, the second write operation, and the erase operation are performed on the memory cell MC. Hereinafter, a case where the first write operation, the second write operation, and the erase operation are performed on the memory cell MCa will be described as an example. In this case, the first word line WL1 is an example of the gate electrode layer, the first source line SL1 is an example of the first wiring, and the first bit line BL1 is an example of the second wiring.

The first write operation is to apply a first write voltage pulse WP1 between the first word line WL1 of the memory cell MCa and at least one of the first source line SL1 and the first bit line BL1. The first write operation is to apply the first write voltage pulse WP1 to the gate insulating layer 11 of the memory cell MCa.

The first write voltage pulse WP1 has a first write voltage Vwrite1 with a first polarity and a first pulse width w1. The first write voltage pulse WP1 is an example of the first voltage pulse. The first write voltage Vwrite1 is an example of the first voltage.

The erase operation is to apply an erase voltage pulse EP between the first word line WL1 of the memory cell MCa and at least one of the first source line SL1 and the first bit line BL1. The erase operation is, for example, to apply the erase voltage pulse EP to the gate insulating layer of the memory cell MC.

The erase voltage pulse EP has an erase voltage Verase with a second polarity opposite to the first polarity and a second pulse width w2. The erase voltage pulse EP is an example of the second voltage pulse. The erase voltage Verase is an example of the second voltage.

For example, it is also possible to simultaneously perform the erase operation on the memory cells MCa to MCd.

In the erase operation, for example, it is also possible to apply the erase voltage pulse EP between the word line WL of the memory cell MC and the channel region 10z of the semiconductor layer 10 using a wiring (not illustrated in FIG. 3) connected to the channel region 10z. In this case, the wiring (not illustrated in FIG. 3) connected to the channel region 10z is an example of the first wiring or the second wiring.

The second write operation is to apply a second write voltage pulse WP2 between the first word line WL1 of the memory cell MCa and at least one of the first source line SL1 and the first bit line BL1. The second write operation is to apply the second write voltage pulse WP2 to the gate insulating layer 11 of the memory cell MCa.

The second write voltage pulse WP2 has a second write voltage Vwrite2 with the first polarity and a third pulse width w3. The second write voltage pulse WP2 is an example of the third voltage pulse. The second write voltage Vwrite2 is an example of the third voltage.

An absolute value of the second write voltage Vwrite2 is smaller than an absolute value of the first write voltage Vwrite1. The third pulse width w3 is, for example, equal to the first pulse width w1.

For example, the first polarity is a polarity in which the word line WL has a positive voltage with respect to the source line SL or the bit line BL, and the second polarity is a polarity in which the word line WL has a negative voltage with respect to the source line SL or the bit line BL. In other words, for example, the first polarity is a polarity in which the word line WL has a positive voltage with respect to the semiconductor layer 10, and the second polarity is a polarity in which the word line WL has a negative voltage with respect to the semiconductor layer 10.

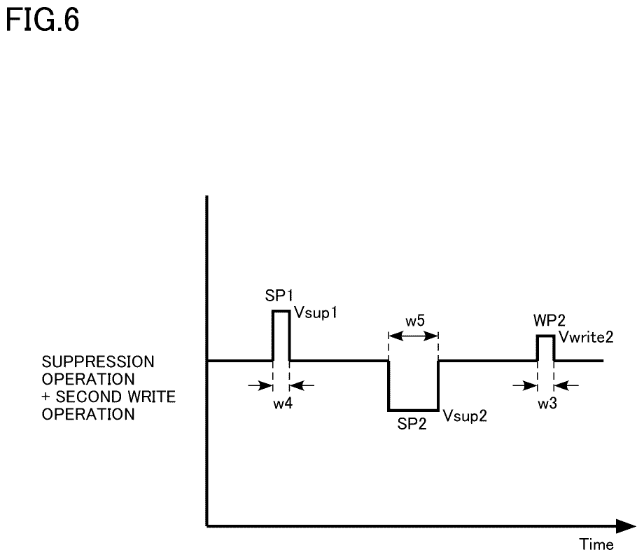

FIG. 6 is a timing chart describing a control method of the semiconductor memory device of the first embodiment. FIG. 6 illustrates a voltage pulse applied to the memory cell MC included in the memory cell array 110. FIG. 6 illustrates a voltage pulse applied to the memory cell MC during the second write operation and a suppression operation performed before the second write operation.

The peripheral circuit 120 of the two-dimensional NOR memory 100 and the controller 200 are capable of executing the suppression operation and the second write operation continuous with the suppression operation to any one memory cell MC selected from the memory cells MCa to MCd, for example. The suppression operation is an example of the first operation.

The suppression operation is an operation for suppressing the occurrence of imprinting in the polarization domain of the memory cell MC. The imprinting means a phenomenon in which a coercive voltage required for polarization inversion changes during a polarization state.

FIG. 6 illustrates a case where the suppression operation and the second write operation are performed on the memory cell MC. For example, when the suppression operation and the second write operation are performed on the memory cell MCa, the first word line WL1 is an example of the gate electrode layer, the first source line SL1 is an example of the first wiring, and the first bit line BL1 is an example of the second wiring.

The suppression operation is to apply a first suppression voltage pulse SP1 and a second suppression voltage pulse SP2 between the first word line WL1 of the memory cell MCa and at least one of the first source line SL1 and the first bit line BL1. The suppression operation is to apply the first suppression voltage pulse SP1 and the second suppression voltage pulse SP2 to the gate insulating layer 11 of the memory cell MCa.

The first suppression voltage pulse SP1 has a first suppression voltage Vsup1 with the first polarity and a fourth pulse width w4. The first suppression voltage pulse SP1 is an example of the fourth voltage pulse. The first suppression voltage Vsup1 is an example of the fourth voltage.

An absolute value of the first suppression voltage Vsup1 is larger than the absolute value of the second write voltage Vwrite2. The absolute value of the first suppression voltage Vsup1 is, for example, equal to or more than the absolute value of the first write voltage Vwrite1. The absolute value of the first suppression voltage Vsup1 is, for example, equal to the absolute value of the first write voltage Vwrite1.

The fourth pulse width w4 of the first suppression voltage pulse SP1 is, for example, equal to or more than the third pulse width w3 of the second write voltage pulse WP2. The fourth pulse width w4 is, for example, larger than the third pulse width w3.

The fourth pulse width w4 is, for example, equal to or more than the first pulse width w1 of the first write voltage pulse WP1. The fourth pulse width w4 is, for example, larger than the first pulse width w1.

The second suppression voltage pulse SP2 has a second suppression voltage Vsup2 with the second polarity and a fifth pulse width w5. The second suppression voltage pulse SP2 is an example of the fifth voltage pulse. The second suppression voltage Vsup2 is an example of the fifth voltage.

An absolute value of the second suppression voltage Vsup2 is larger than the absolute value of the second write voltage Vwrite2. The absolute value of the second suppression voltage Vsup2 is, for example, equal to or more than an absolute value of the erase voltage Verase. The absolute value of the second suppression voltage Vsup2 is, for example, equal to the absolute value of the erase voltage Verase.

The fifth pulse width w5 of the second suppression voltage pulse SP2 is, for example, equal to or more than the third pulse width w3 of the second write voltage pulse WP2. The fifth pulse width w5 is, for example, larger than the third pulse width. The fifth pulse width w5 is, for example, equal to or more than the second pulse width w2 of the erase voltage pulse EP.

The applying of the second suppression voltage pulse SP2 is performed consecutively after the applying of the first suppression voltage pulse SP1. For example, no other pulse is applied between the applying of the first suppression voltage pulse SP1 and the applying of the second suppression voltage pulse SP2.

The suppression operation is consecutive with the second write operation. After the suppression operation is performed, the second write operation is consecutively performed.

The applying of the first suppression voltage pulse SP1, the applying of the second suppression voltage pulse SP2, and the applying of the second write voltage pulse WP2 are consecutively performed. For example, no other pulse is applied between the applying of the second suppression voltage pulse SP2 and the applying of the second write voltage pulse WP2.

Next, the function and effect of the semiconductor memory device of the first embodiment will be described.

In a nonvolatile semiconductor memory device in which a field effect transistor containing a ferroelectric in a gate insulating layer is used as a memory cell, there may be a problem in that a desired write operation or erase operation cannot be performed on the memory cell, and the threshold voltage of the transistor cannot be controlled to a desired threshold voltage. In other words, a failure in writing data to a memory cell or a failure in data erase operation may occur.

One of causes of a failure in writing data to a memory cell or a failure in data erase operation is considered to be imprinting.

As is clear from FIG. 4, when only the second write operation and the erase operation are repeated for one memory cell MC, polarization inversion is repeated in the low coercive voltage domain, but polarization inversion does not occur at all in the high coercive voltage domain. For this reason, imprinting does not occur in the low coercive voltage domain in which polarization inversion is repeated, but imprinting may become apparent in the high coercive voltage domain in which polarization inversion does not occur at all. Therefore, even when the write operation and the erase operation on the memory cell MC are repeatedly performed, imprinting may occur in the memory cell MC, and a write failure or an erase failure may occur in the memory cell MC.

For example, when the memory cell MC is a memory not using the intermediate state, that is, is not a multi-level memory, only the first write operation and the erase operation are repeated in the memory cell MC. In this case, when the polarization inversion is repeated in both the low coercive voltage domain and the high coercive voltage domain, that is, the memory cell is not a multi-level memory, imprinting is less likely to occur in the memory cell MC and a write failure or an erase failure of the memory cell MC is suppressed as long as the write operation and the erase operation on the memory cell MC is repeatedly performed.

As described above, even when the write operation and the erase operation on the memory cell MC are repeatedly performed, there is a problem unique to the multi-level memory using a ferroelectric in that imprinting may occur in the memory cell MC. According to the study of the inventors, it has been found that a change in coercive voltage of imprinting occurring when only the second write operation and the erase operation are repeated in the memory cell MC is larger than that of imprinting occurring when the memory cell MC is simply left without performing the second write operation and the erase operation. This is considered to be because the imprinting of the high coercive voltage domain is accelerated by applying voltage stress associated with the second write operation and the erase operation to the high coercive voltage domain in which the polarization inversion does not occur.

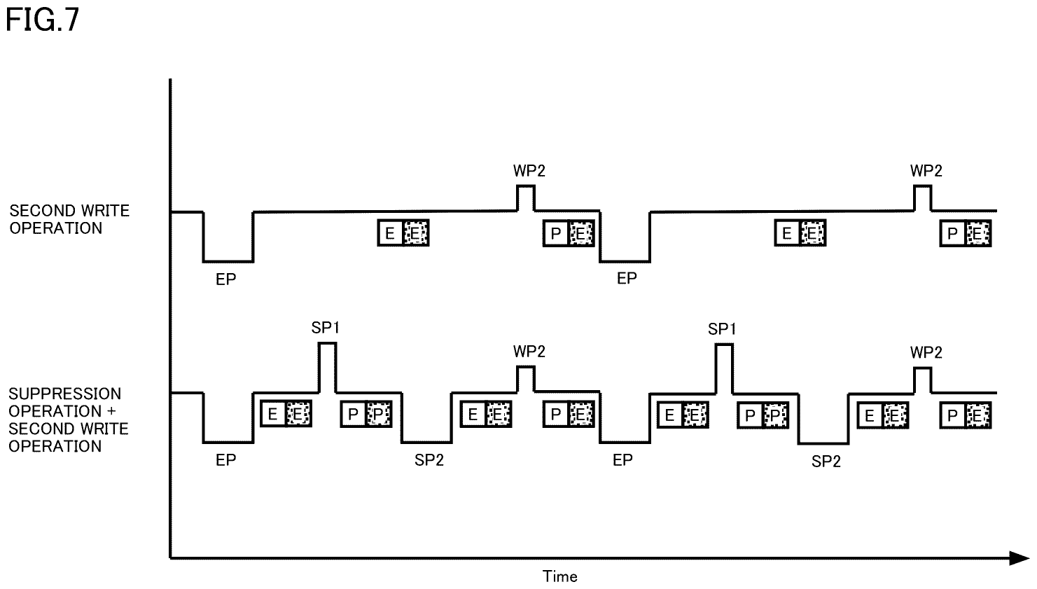

FIG. 7 is an explanatory diagram of the function and effect of the semiconductor memory device of the first embodiment. FIG. 7 is a timing chart describing a control method of the semiconductor memory device of the first embodiment. FIG. 7 illustrates voltage pulses applied to the memory cell MC when the suppression operation is not performed before the second write operation and when the suppression operation is performed before the second write operation.

FIG. 7 schematically illustrates polarization states of the low coercive voltage domain and the high coercive voltage domain before and after applying each pulse. The left side of the two adjacent squares shows the polarization state of the low coercive voltage domain, and the right side shows the polarization state of the high coercive voltage domain. It is indicated whether each domain is in the erase state (E) or the program state (P).

As illustrated in FIG. 7, when the suppression operation is not performed before the second write operation, even if the second write operation and the erase operation are repeatedly performed, the high coercive voltage domain is maintained in the erase state (E), and the state does not change. On the other hand, as in the control method of the semiconductor memory device of the first embodiment, when the suppression operation is performed at all times before the second write operation, polarization inversion occurs in the high coercive voltage domain, and the high coercive voltage domain transitions between the erase state (E) and the program state (P).

Since the suppression operation is performed at all times before the second write operation, polarization inversion can be caused in all polarization domains of the memory cell MC. Therefore, imprinting of the memory cell MC is suppressed, and a write failure or an erase failure of the memory cell MC is suppressed. Therefore, a semiconductor memory device having excellent characteristics including the two-dimensional NOR memory 100 can be realized.

From the viewpoint of suppressing imprinting occurring in the memory cell MC, the absolute value of the first suppression voltage Vsup1 is preferably equal to or more than the absolute value of the first write voltage Vwrite1. From the same viewpoint, the fourth pulse width w4 of the first suppression voltage pulse SP1 is preferably equal to or more than the third pulse width w3 of the second write voltage pulse WP2. From the same viewpoint, the fourth pulse width w4 is preferably equal to or more than the first pulse width w1 of the first write voltage pulse WP1.

From the viewpoint of suppressing imprinting occurring in the memory cell MC, the absolute value of the second suppression voltage Vsup2 is preferably equal to or more than the absolute value of the erase voltage Verase. From the same viewpoint, the fifth pulse width w5 of the second suppression voltage pulse SP2 is preferably equal to or more than the third pulse width w3 of the second write voltage pulse WP2. From the same viewpoint, the fifth pulse width w5 is preferably equal to or more than the second pulse width w2 of the erase voltage pulse EP.

### Modification

A modification of the semiconductor memory device of the first embodiment is different from the semiconductor memory device of the first embodiment in that the second write operation is to apply a third voltage pulse having a third voltage with the second polarity having a smaller absolute value than an absolute value of the second voltage and a third pulse width between the gate electrode layer and at least one of the first wiring and the second wiring, and the first operation is to apply a fourth voltage pulse having a fourth voltage with the second polarity having a larger absolute value than the absolute value of the third voltage and a fourth pulse width and apply a fifth voltage pulse having a fifth voltage with the first polarity having a larger absolute value than the absolute value of the third voltage and a fifth pulse width between the gate electrode layer and at least one of the first wiring and the second wiring, the applying of the fifth voltage pulse being consecutive with the applying of the fourth voltage pulse.

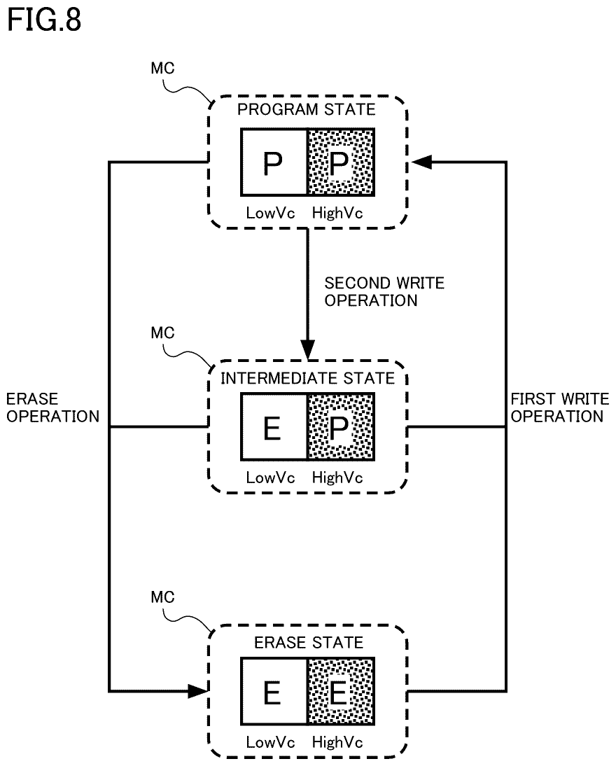

FIG. 8 is an explanatory diagram of a memory cell of a modification of the semiconductor memory device of the first embodiment. FIG. 8 is an explanatory diagram of a possible level of the memory cell MC.

As illustrated in FIG. 8, the memory cell MC can take three states of an erase state, a program state, and an intermediate state. The transistor of the memory cell MC can have a threshold voltage corresponding to each state.

As illustrated in FIG. 8, it is considered that there are polarization domains having two different coercive voltages (Vc) in the ferroelectric of the memory cell MC. The polarization domains are a low coercive voltage domain (Low Vc domain) having a low coercive voltage and a high coercive voltage domain (High Vc domain) having a high coercive voltage.

When the memory cell MC is in the erase state, the low coercive voltage domain is in the erase state (E) and the high coercive voltage domain is in the erase state (E). When the memory cell MC is in the intermediate state, the low coercive voltage domain is in the erase state (E) and the high coercive voltage domain is in the program state (P). When the memory cell MC is in the program state, the low coercive voltage domain is in the program state (P) and the high coercive voltage domain is in the program state (P).

For example, by performing the first write operation on the memory cell MC in the erase state, polarization inversion occurs in the low coercive voltage domain and the high coercive voltage domain, and the low coercive voltage domain and the high coercive voltage domain are in the program state (P). As a result, the memory cell MC transitions from the erase state to the program state.

For example, by performing the second write operation on the memory cell MC in the program state, domain polarization inversion occurs in only the low coercive voltage domain, the low coercive voltage domain is in the erase state (E), and the high coercive voltage domain remains in the program state (P). As a result, the memory cell MC transitions from the program state to the intermediate state.

For example, by performing the erase operation on the memory cell MC in the program state, polarization inversion of the low coercive voltage domain and the high coercive voltage domain occurs, and the low coercive voltage domain and the high coercive voltage domain are in the erase state (E). As a result, the memory cell MC transitions from the program state to the erase state.

For example, by performing the erase operation on the memory cell MC in the intermediate state, polarization inversion of the high coercive voltage domain occurs, and the high coercive voltage domain is in the erase state (E). As a result, the memory cell MC transitions from the intermediate state to the erase state.

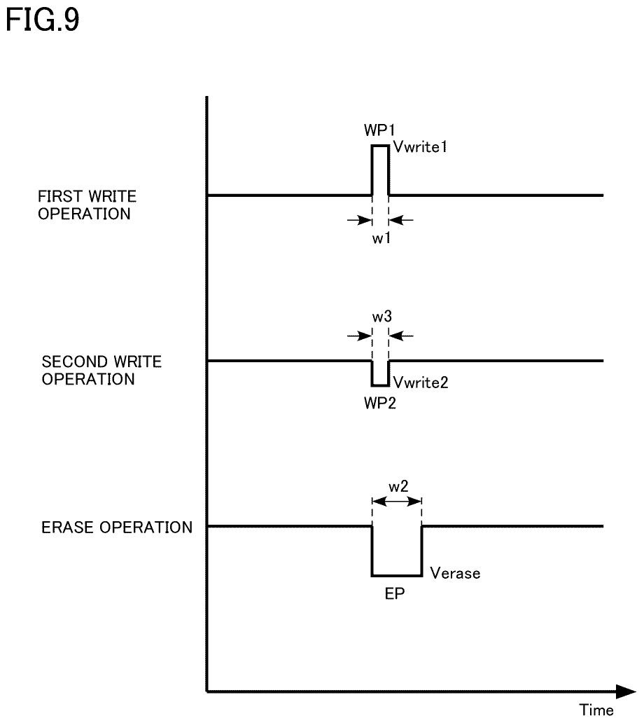

FIG. 9 is a timing chart describing a control method of a modification of the semiconductor memory device of the first embodiment. FIG. 9 illustrates a voltage pulse applied to the memory cell MC included in the memory cell array 110. FIG. 9 illustrates a voltage pulse applied to the memory cell MC during the first write operation, the second write operation, and the erase operation.

FIG. 9 illustrates a case where the first write operation, the second write operation, and the erase operation are performed on the memory cell MC. The first write operation and the erase operation are the same as in the first embodiment. Hereinafter, a case where the second write operation is performed on the memory cell MCa will be described as an example. In this case, the first word line WL1 is an example of the gate electrode layer, the first source line SL1 is an example of the first wiring, and the first bit line BL1 is an example of the second wiring.

The second write operation is to apply the second write voltage pulse WP2 between the first word line WL1 of the memory cell MCa and at least one of the first source line SL1 and the first bit line BL1. The second write operation is to apply the second write voltage pulse WP2 to the gate insulating layer 11 of the memory cell MCa. Before performing the second write operation, the memory cell MCa necessarily needs to be in the program state. For example, the first write operation is performed immediately before performing the second write operation on the memory cell MCa. For example, immediately before the second write operation is performed, the data of the memory cell MCa is read, and it is confirmed that the data is in the program state.

The second write voltage pulse WP2 has a second write voltage Vwrite2 with the second polarity and a third pulse width w3. The second write voltage pulse WP2 is an example of the third voltage pulse. The second write voltage Vwrite2 is an example of the third voltage.

The absolute value of the second write voltage Vwrite2 is smaller than the absolute value of the erase voltage Verase. The third pulse width w3 of the second write voltage pulse WP2 is, for example, equal to the first pulse width w1 of the first write voltage pulse WP1.

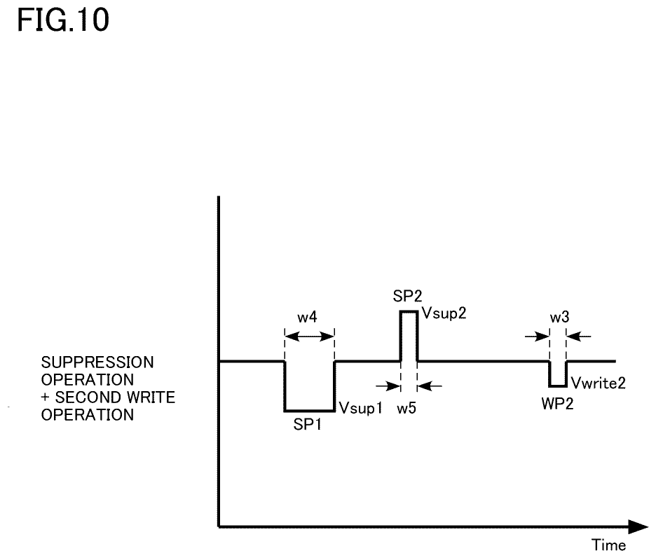

FIG. 10 is a timing chart describing a control method of a modification of the semiconductor memory device of the first embodiment. FIG. 10 illustrates a voltage pulse applied to the memory cell MC included in the memory cell array 110. FIG. 10 illustrates a voltage pulse applied to the memory cell MC during the second write operation and a suppression operation performed before the second write operation.

FIG. 10 illustrates a case where the suppression operation and the second write operation are performed on the memory cell MC. For example, when the suppression operation and the second write operation are performed on the memory cell MCa, the first word line WL1 is an example of the gate electrode layer, the first source line SL1 is an example of the first wiring, and the first bit line BL1 is an example of the second wiring.

The suppression operation is to apply a first suppression voltage pulse SP1 and a second suppression voltage pulse SP2 between the first word line WL1 of the memory cell MCa and at least one of the first source line SL1 and the first bit line BL1. The suppression operation is to apply the first suppression voltage pulse SP1 and the second suppression voltage pulse SP2 to the gate insulating layer 11 of the memory cell MCa.

The first suppression voltage pulse SP1 has a first suppression voltage Vsup1 with the second polarity and a fourth pulse width w4. The first suppression voltage pulse SP1 is an example of the fourth voltage pulse. The first suppression voltage Vsup1 is an example of the fourth voltage.

An absolute value of the first suppression voltage Vsup1 is larger than the absolute value of the second write voltage Vwrite2. The absolute value of the first suppression voltage Vsup1 is, for example, equal to or more than the absolute value of the erase voltage Verase. The absolute value of the first suppression voltage Vsup1 is, for example, equal to the absolute value of the erase voltage Verase.

The fourth pulse width w4 of the first suppression voltage pulse SP1 is, for example, equal to or more than the third pulse width w3 of the second write voltage pulse WP2. The fourth pulse width w4 is, for example, larger than the third pulse width w3.

The fourth pulse width w4 is, for example, equal to or more than the second pulse width w2 of the erase voltage pulse EP. The fourth pulse width w4 is, for example, larger than the second pulse width w2.

The second suppression voltage pulse SP2 has a second suppression voltage Vsup2 with the first polarity and a fifth pulse width w5. The second suppression voltage pulse SP2 is an example of the fifth voltage pulse. The second suppression voltage Vsup2 is an example of the fifth voltage.

An absolute value of the second suppression voltage Vsup2 is larger than the absolute value of the second write voltage Vwrite2. The absolute value of the second suppression voltage Vsup2 is, for example, equal to or more than the absolute value of the first write voltage Vwrite1. The absolute value of the second suppression voltage Vsup2 is, for example, equal to the absolute value of the first write voltage Vwrite1.

The fifth pulse width w5 of the second suppression voltage pulse SP2 is, for example, equal to or more than the third pulse width w3 of the second write voltage pulse WP2. The fifth pulse width w5 is, for example, larger than the third pulse width w3. The fifth pulse width w5 is, for example, equal to or more than the first pulse width w1.

The applying of the second suppression voltage pulse SP2 is performed consecutively after the applying of the first suppression voltage pulse SP1. For example, no other pulse is applied between the applying of the first suppression voltage pulse SP1 and the applying of the second suppression voltage pulse SP2.

The suppression operation is consecutive with the second write operation. After the suppression operation is performed, the second write operation is consecutively performed.

The applying of the first suppression voltage pulse SP1, the applying of the second suppression voltage pulse SP2, and the applying of the second write voltage pulse WP2 are consecutively performed. For example, no other pulse is applied between the applying of the second suppression voltage pulse SP2 and the applying of the second write voltage pulse WP2.

Next, the function and effect of the modification of the semiconductor memory device of the first embodiment will be described.

As is clear from FIG. 8, when only the first write operation and the second write operation are repeated for one memory cell MC, polarization inversion is repeated in the low coercive voltage domain, but polarization inversion does not occur at all in the high coercive voltage domain. For this reason, imprinting does not occur in the low coercive voltage domain in which polarization inversion is repeated, but imprinting may become apparent in the high coercive voltage domain in which polarization inversion does not occur at all. Therefore, even when the write operation on the memory cell MC is repeatedly performed, imprinting may occur in the memory cell MC, and a write failure or an erase failure may occur in the memory cell MC.

For example, when the memory cell MC is a memory not using the intermediate state, that is, is not a multi-level memory, only the first write operation and the erase operation are repeated in the memory cell MC. In this case, when the polarization inversion is repeated in both the low coercive voltage domain and the high coercive voltage domain, that is, the memory cell is not a multi-level memory, imprinting is less likely to occur in the memory cell MC and a write failure or an erase failure of the memory cell MC is suppressed as long as the write operation and the erase operation on the memory cell MC is repeatedly performed.

As described above, even when the write operation on the memory cell MC is repeatedly performed, there is a problem unique to the multi-level memory in that imprinting may occur in the memory cell MC. According to the study of the inventors, it has been found that a change in coercive voltage of imprinting occurring when only the first write operation and the second write operation are repeated in the memory cell MC is larger than that of imprinting occurring when the memory cell MC is simply left without performing the first write operation and the second write operation.

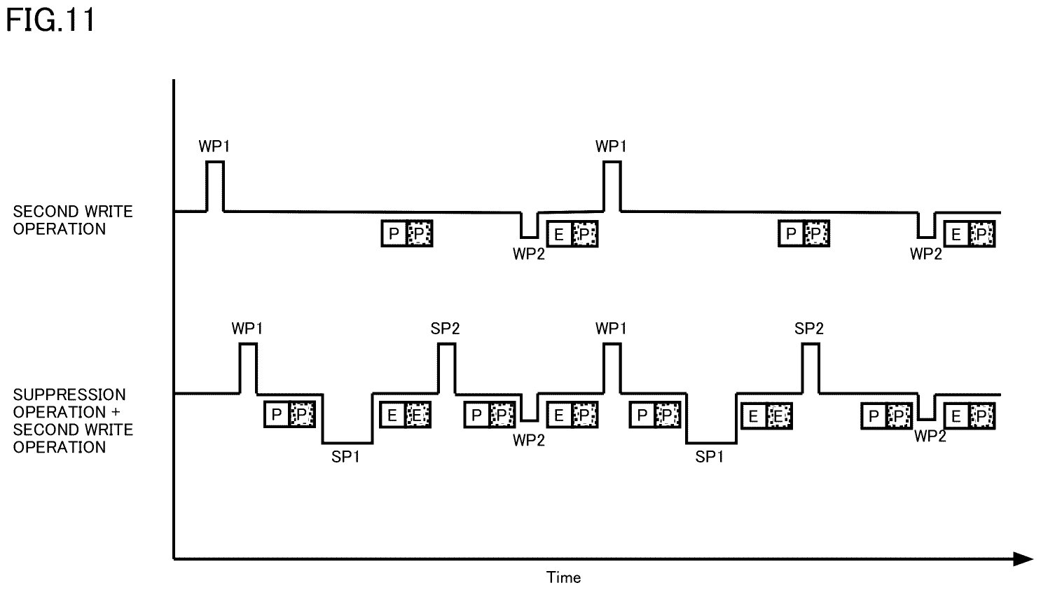

FIG. 11 is an explanatory diagram of the function and effect of a modification of the semiconductor memory device of the first embodiment. FIG. 11 is a timing chart describing a control method of a modification of the semiconductor memory device of the first embodiment. FIG. 11 illustrates voltage pulses applied to the memory cell MC when the suppression operation is not performed before the second write operation and when the suppression operation is performed before the second write operation.

FIG. 11 schematically illustrates polarization states of the low coercive voltage domain and the high coercive voltage domain before and after applying each pulse. The left side of the two adjacent squares shows the polarization state of the low coercive voltage domain, and the right side shows the polarization state of the high coercive voltage domain. It is indicated whether each domain is in the erase state (E) or the program state (P).

As illustrated in FIG. 11, when the suppression operation is not performed before the second write operation, even if the first write operation and the second write operation are repeatedly performed, the high coercive voltage domain is maintained in the program state (P), and the state does not change. On the other hand, as in the control method of the modification of the semiconductor memory device of the first embodiment, when the suppression operation is performed at all times before the second write operation, polarization inversion occurs in the high coercive voltage domain, and the high coercive voltage domain transitions between the erase state (E) and the program state (P).

Since the suppression operation is performed at all times before the second write operation, polarization inversion can be caused in all polarization domains of the memory cell MC. Therefore, according to the modification of the first embodiment, similarly to the first embodiment, imprinting of the memory cell MC is suppressed, and a write failure or an erase failure of the memory cell MC is suppressed. Therefore, a semiconductor memory device having excellent characteristics including the two-dimensional NOR memory 100 can be realized.

From the viewpoint of suppressing imprinting occurring in the memory cell MC, the absolute value of the first suppression voltage Vsup1 is preferably equal to or more than the absolute value of the erase voltage Verase. From the same viewpoint, the fourth pulse width w4 of the first suppression voltage pulse SP1 is preferably equal to or more than the third pulse width w3 of the second write voltage pulse WP2. From the same viewpoint, the fourth pulse width w4 is preferably equal to or more than the second pulse width w2 of the erase voltage pulse EP.

From the viewpoint of suppressing imprinting occurring in the memory cell MC, the absolute value of the second suppression voltage Vsup2 is preferably equal to or more than the absolute value of the first write voltage Vwrite1. From the same viewpoint, the fifth pulse width w5 of the second suppression voltage pulse SP2 is preferably equal to or more than the third pulse width w3 of the second write voltage pulse WP2. From the same viewpoint, the fifth pulse width w5 is preferably equal to or more than the first pulse width w1 of the first write voltage pulse WP1.

As described above, according to the first embodiment and the modification, imprinting of a memory cell is suppressed, and a semiconductor memory device having excellent characteristics can be realized.

### Second Embodiment

A semiconductor memory device of a second embodiment includes: a memory cell including a semiconductor layer, a gate electrode layer, and a gate insulating layer containing a ferroelectric and provided between the semiconductor layer and the gate electrode layer; a first wiring and a second wiring electrically connected to the semiconductor layer; and a control circuit configured to control the memory cell. The control circuit is capable of executing a first write operation to the memory cell. The first write operation is to apply a first voltage pulse having a first voltage with a first polarity and a first pulse width between the gate electrode layer and at least one of the first wiring and the second wiring. The control circuit is capable of executing an erase operation to the memory cell. The erase operation is to apply a second voltage pulse having a second voltage with a second polarity opposite to the first polarity and a second pulse width between the gate electrode layer and at least one of the first wiring and the second wiring. The control circuit is capable of executing a second write operation to the memory cell. The second write operation is to apply a third voltage pulse having a third voltage with the first polarity having a smaller absolute value than an absolute value of the first voltage and a third pulse width between the gate electrode layer and at least one of the first wiring and the second wiring. The control circuit is capable of determining whether or not the number of times of execution of the second write operation to the memory cell has reached a predetermined first number of times. The control circuit is capable of executing a first operation to the memory cell when it is determined that the number of times of execution has reached the predetermined first number of times. The first operation is to apply a fourth voltage pulse having a fourth voltage with the first polarity having a larger absolute value than the absolute value of the third voltage and a fourth pulse width and apply a fifth voltage pulse having a fifth voltage with the second polarity having a larger absolute value than the absolute value of the third voltage and a fifth pulse width between the gate electrode layer and at least one of the first wiring and the second wiring, the applying of the fifth voltage pulse being consecutive with the applying of the fourth voltage pulse.

The semiconductor memory device of the second embodiment is different from the semiconductor memory device of the first embodiment in that a recovery operation is performed. Hereinafter, description of contents overlapping with the first embodiment may be partially omitted.

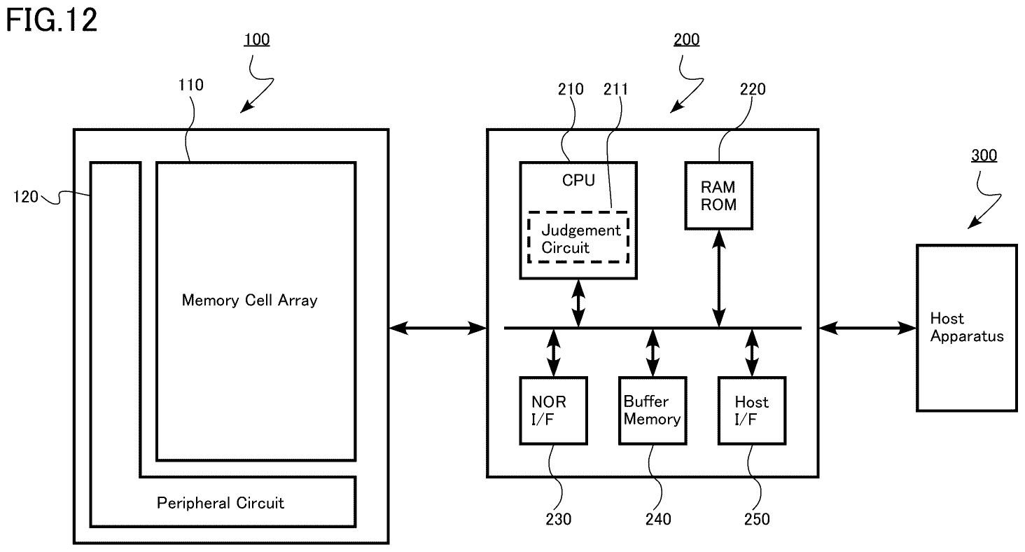

FIG. 12 is a block diagram of a memory system including a semiconductor memory device of a second embodiment. The memory system of the second embodiment includes, for example, a two-dimensional NOR memory 100, a controller 200, and a host apparatus 300. The semiconductor memory device of the second embodiment includes, for example, the two-dimensional NOR memory 100 and the controller 200.

The peripheral circuit 120 of the two-dimensional NOR memory 100 and the controller 200 are examples of the control circuit of the second embodiment.

The processor 210 of the second embodiment includes a judgement circuit 211 unlike the processor 210 of the first embodiment.

The built-in memory 220 stores, for example, the number of times of execution of the second write operation executed to each of the memory cells included in the two-dimensional NOR memory 100. The built-in memory 220 stores, for example, a predetermined first number of times of the second write operation serving as a criterion for determining whether or not to execute the recovery operation. The judgement circuit 211 is capable of determining whether or not the number of times of execution of the second write operation to a specific memory cell has reached the predetermined first number of times on the basis of the number of times of execution of the second write operation and the predetermined first number of times of the second write operation stored in the built-in memory 220.

The peripheral circuit 120 of the two-dimensional NOR memory 100 and the controller 200 are capable of executing the recovery operation to a specific memory cell when it is determined that the number of times of execution of the second write operation to the specific memory cell has reached the predetermined first number of times. The recovery operation is an example of the first operation.

A possible level of the memory cell MC of the semiconductor memory device of the second embodiment is the same as in the first embodiment described with reference to FIG. 4. The first write operation, the second write operation, and the erase operation in the control of the semiconductor memory device of the second embodiment are the same as in the semiconductor memory device of the first embodiment.

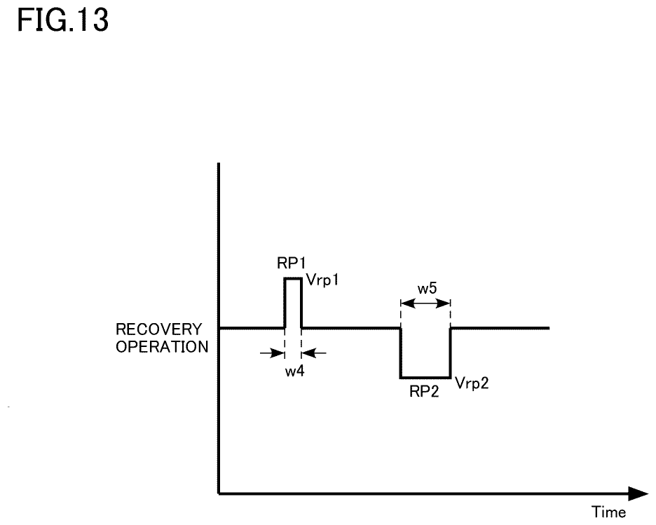

FIG. 13 is a timing chart describing a control method of the semiconductor memory device of the second embodiment. FIG. 13 illustrates a voltage pulse applied to the memory cell MC included in the memory cell array 110. FIG. 13 illustrates the voltage pulse applied to the memory cell MC during the recovery operation.

The recovery operation is an operation for recovering imprinting having occurred in the polarization domain of the memory cell MC.

For example, when the recovery operation is performed on the memory cell MCa, the first word line WL1 is an example of the gate electrode layer, the first source line SL1 is an example of the first wiring, and the first bit line BL1 is an example of the second wiring.

The recovery operation is to apply a first recovery voltage pulse RP1 and a second recovery voltage pulse RP2 between the first word line WL1 of the memory cell MCa and at least one of the first source line SL1 and the first bit line BL1. The recovery operation is to apply the first recovery voltage pulse RP1 and the second recovery voltage pulse RP2 to the gate insulating layer 11 of the memory cell MCa.

The first recovery voltage pulse RP1 has a first recovery voltage Vrp1 with the first polarity and a fourth pulse width w4. The first recovery voltage pulse RP1 is an example of the fourth voltage pulse. The first recovery voltage Vrp1 is an example of the fourth voltage.

An absolute value of the first recovery voltage Vrp1 is larger than the absolute value of the second write voltage Vwrite2. The absolute value of the first recovery voltage Vrp1 is, for example, equal to or more than the absolute value of the first write voltage Vwrite1. The absolute value of the first recovery voltage Vrp1 is, for example, equal to the absolute value of the first write voltage Vwrite1.

The fourth pulse width w4 of the first recovery voltage pulse RP1 is, for example, equal to or more than the third pulse width w3 of the second write voltage pulse WP2. The fourth pulse width w4 is, for example, larger than the third pulse width w3.

The fourth pulse width w4 is, for example, equal to or more than the first pulse width w1 of the first write voltage pulse WP1. The fourth pulse width w4 is, for example, larger than the first pulse width w1.

The second recovery voltage pulse RP2 has a second recovery voltage Vrp2 with the second polarity and a fifth pulse width w5. The second recovery voltage pulse RP2 is an example of the fifth voltage pulse. The second recovery voltage Vrp2 is an example of the fifth voltage.

An absolute value of the second recovery voltage Vrp2 is larger than the absolute value of the second write voltage Vwrite2. The absolute value of the second recovery voltage Vrp2 is, for example, equal to or more than the absolute value of the erase voltage Verase. The absolute value of the second recovery voltage Vrp2 is, for example, equal to the absolute value of the erase voltage Verase.

The fifth pulse width w5 of the second recovery voltage pulse RP2 is, for example, equal to or more than the third pulse width w3 of the second write voltage pulse WP2. The fifth pulse width w5 is, for example, larger than the third pulse width. The fifth pulse width w5 is, for example, equal to or more than the second pulse width w2.

The second recovery voltage pulse RP2 is, for example, performed consecutively after the applying of the first recovery voltage pulse RP1. No other pulse is, for example, applied between the applying of the first recovery voltage pulse RP1 and the applying of the second recovery voltage pulse RP2.

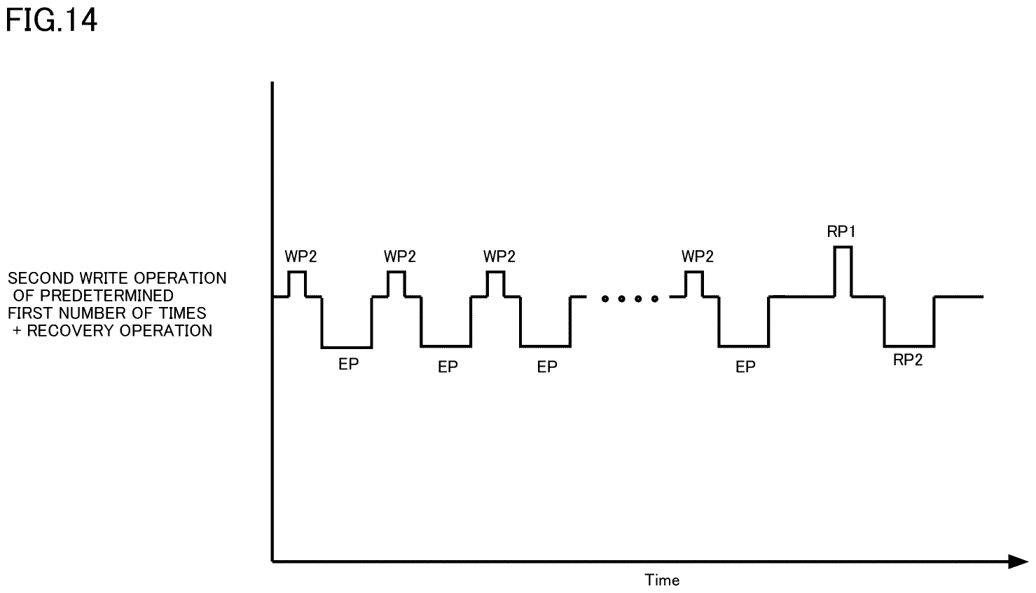

FIG. 14 is a timing chart describing a control method of the semiconductor memory device of the second embodiment. FIG. 14 illustrates a voltage pulse applied to the memory cell MC included in the memory cell array 110.

As illustrated in FIG. 14, when the number of times of execution of the second write operation to the memory cell MC has reached the predetermined first number of times, the recovery operation is executed. The predetermined first number of times is, for example, the number of times until the imprinting becomes apparent by execution of the second write operation of the memory cell MC is measured in advance, and is set to the number of times sufficiently less than the number of times.

The number of times of execution of the second write operation is the number of times when the second write voltage pulse WP2 is applied to the memory cell MC.

The predetermined first number of times is, for example, the number of times when the second write operation is consecutively performed without interposing the first write operation. In this case, the control circuit is configured to determine whether or not the number of times when the second write operation is consecutively performed without interposing the first write operation has reached the predetermined first number of times.

The recovery operation is, for example, consecutive with the final second write operation. The recovery operation is, for example, performed consecutively after the second write operation is performed.

The applying of the second write voltage pulse WP2, the applying of the first recovery voltage pulse RP1, and the applying of the second recovery voltage pulse RP2 are, for example, consecutively performed.

The recovery operation may be consecutively performed a plurality of times. In this case, the control circuit is configured to consecutively perform the recovery operation a plurality of times.

Next, the function and effect of the semiconductor memory device of the second embodiment will be described.

As described in the first embodiment with reference to FIG. 4, when only the second write operation and the erase operation are repeated for one memory cell MC, polarization inversion is repeated in the low coercive voltage domain, but polarization inversion does not occur at all in the high coercive voltage domain. For this reason, imprinting does not occur in the low coercive voltage domain in which polarization inversion is repeated, but imprinting may become apparent in the high coercive voltage domain in which polarization inversion does not occur at all. Therefore, even when the write operation and the erase operation on the memory cell MC are repeatedly performed, imprinting may occur in the memory cell MC, and a write failure or an erase failure may occur in the memory cell MC. This problem is a problem unique to a multi-level memory using a ferroelectric.

As described above, even when the write operation and the erase operation on the memory cell MC are repeatedly performed, there is a problem unique to the multi-level memory using a ferroelectric in that imprinting may occur in the memory cell MC. According to the study of the inventors, it has been found that a change in coercive voltage of imprinting occurring when only the second write operation and the erase operation are repeated in the memory cell MC is larger than that of imprinting occurring when the memory cell MC is simply left without performing the second write operation and the erase operation.

The semiconductor memory device of the second embodiment performs a recovery operation for recovering the imprinting of the memory cell MC when the second write operation for accelerating the imprinting of the memory cell MC reaches the predetermined first number of times. Therefore, imprinting of the memory cell MC is effectively recovered, and a write failure or an erase failure of the memory cell MC is suppressed. Therefore, a semiconductor memory device having excellent characteristics including the two-dimensional NOR memory 100 can be realized.

From the viewpoint of effectively recovering imprinting occurring in the memory cell MC, the absolute value of the first recovery voltage Vrp1 is preferably equal to or more than the absolute value of the first write voltage Vwrite1. From the same viewpoint, the fourth pulse width w4 of the first recovery voltage pulse RP1 is preferably equal to or more than the third pulse width w3 of the second write voltage pulse WP2. From the same viewpoint, the fourth pulse width w4 is preferably equal to or more than the first pulse width w1 of the first write voltage pulse WP1. From the viewpoint of effectively recovering imprinting occurring in the memory cell MC, the absolute value of the second recovery voltage Vrp2 is preferably equal to or more than the absolute value of the erase voltage Verase. From the same viewpoint, the fifth pulse width w5 of the second recovery voltage pulse RP2 is preferably equal to or more than the third pulse width w3 of the second write voltage pulse WP2. From the same viewpoint, the fifth pulse width w5 is preferably equal to or more than the second pulse width w2 of the erase voltage pulse EP.

### Modification

A modification of the semiconductor memory device of the second embodiment is different from the semiconductor memory device of the second embodiment in that the second write operation is to apply a third voltage pulse having a third voltage with the second polarity having a smaller absolute value than an absolute value of the second voltage and a third pulse width between the gate electrode layer and at least one of the first wiring and the second wiring, and the first operation is to apply a fourth voltage pulse having a fourth voltage with the second polarity having a larger absolute value than the absolute value of the third voltage and a fourth pulse width and apply a fifth voltage pulse having a fifth voltage with the first polarity having a larger absolute value than the absolute value of the third voltage and a fifth pulse width between the gate electrode layer and at least one of the first wiring and the second wiring, the applying of the fifth voltage pulse being consecutive with the applying of the fourth voltage pulse.

A possible level of the memory cell MC of the modification of the semiconductor memory device of the second embodiment is the same as in the modification of the first embodiment described with reference to FIG. 8. The first write operation, the second write operation, and the erase operation in the control of the modification of the semiconductor memory device of the second embodiment are the same as in the semiconductor memory device of the modification of the first embodiment.

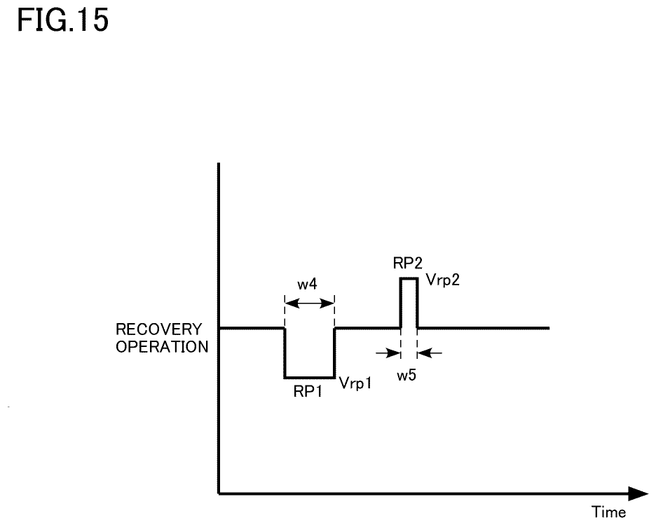

FIG. 15 is a timing chart describing a control method of a modification of the semiconductor memory device of the second embodiment. FIG. 15 illustrates a voltage pulse applied to the memory cell MC included in the memory cell array 110. FIG. 15 illustrates the voltage pulse applied to the memory cell MC during the recovery operation.

The first recovery voltage pulse RP1 has a first recovery voltage Vrp1 with the second polarity and a fourth pulse width w4. The first recovery voltage pulse RP1 is an example of the fourth voltage pulse. The first recovery voltage Vrp1 is an example of the fourth voltage.

An absolute value of the first recovery voltage Vrp1 is larger than the absolute value of the second write voltage Vwrite2. The absolute value of the first recovery voltage Vrp1 is, for example, equal to or more than the absolute value of the erase voltage Verase. The absolute value of the first recovery voltage Vrp1 is, for example, equal to the absolute value of the erase voltage Verase.

The fourth pulse width w4 of the first recovery voltage pulse RP1 is, for example, equal to or more than the third pulse width w3 of the second write voltage pulse WP2. The fourth pulse width w4 is, for example, larger than the third pulse width w3.

The fourth pulse width w4 is, for example, equal to or more than the second pulse width w2 of the erase voltage pulse EP. The fourth pulse width w4 is, for example, larger than the second pulse width w2.

The second recovery voltage pulse RP2 has a second recovery voltage Vrp2 with the first polarity and a fifth pulse width w5. The second recovery voltage pulse RP2 is an example of the fifth voltage pulse. The second recovery voltage Vrp2 is an example of the fifth voltage.

An absolute value of the second recovery voltage Vrp2 is larger than the absolute value of the second write voltage Vwrite2. The absolute value of the second recovery voltage Vrp2 is, for example, equal to or more than the absolute value of the first write voltage Vwrite1. The absolute value of the second recovery voltage Vrp2 is, for example, equal to the absolute value of the first write voltage Vwrite1.

The fifth pulse width w5 of the second recovery voltage pulse RP2 is, for example, equal to or more than the third pulse width w3 of the second write voltage pulse WP2. The fifth pulse width w5 is, for example, larger than the third pulse width w3. The fifth pulse width w5 is, for example, equal to or more than the first pulse width w1 of the first write voltage pulse.

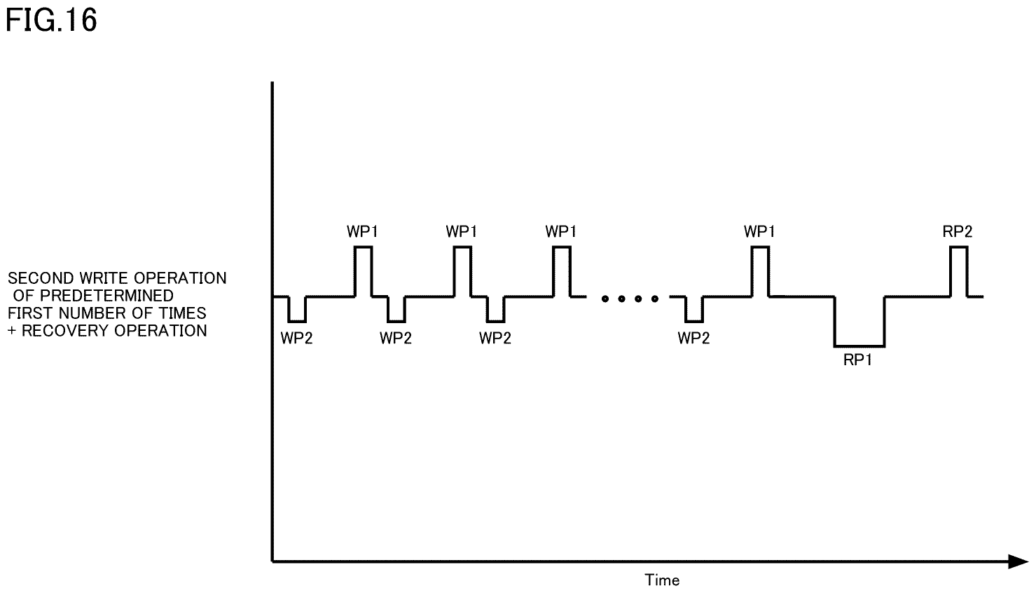

FIG. 16 is a timing chart describing a control method of a modification of the semiconductor memory device of the second embodiment. FIG. 16 illustrates a voltage pulse applied to the memory cell MC included in the memory cell array 110.

As illustrated in FIG. 16, when the number of times of execution of the second write operation has reached the predetermined first number of times, the recovery operation is executed.

Next, the function and effect of the modification of the semiconductor memory device of the second embodiment will be described.

As described in the first embodiment with reference to FIG. 8, when only the first write operation and the second write operation are repeated for one memory cell MC, polarization inversion is repeated in the low coercive voltage domain, but polarization inversion does not occur at all in the high coercive voltage domain. For this reason, imprinting does not occur in the low coercive voltage domain in which polarization inversion is repeated, but imprinting may become apparent in the high coercive voltage domain in which polarization inversion does not occur at all. Therefore, even when the write operation on the memory cell MC is repeatedly performed, imprinting may occur in the memory cell MC, and a write failure or an erase failure may occur in the memory cell MC. This problem is a problem unique to a multi-level memory using a ferroelectric.

As described above, even when the write operation on the memory cell MC is repeatedly performed, there is a problem unique to the multi-level memory in that imprinting may occur in the memory cell MC. According to the study of the inventors, it has been found that a change in coercive voltage of imprinting occurring when only the first write operation and the second write operation are repeated in the memory cell MC is larger than that of imprinting occurring when the memory cell MC is simply left without performing the first write operation and the second write operation.

The modification of the semiconductor memory device of the second embodiment performs a recovery operation for recovering the imprinting of the memory cell MC when the second write operation for accelerating the imprinting of the memory cell MC reaches the predetermined first number of times. Therefore, imprinting of the memory cell MC is effectively recovered, and a write failure or an erase failure of the memory cell MC is suppressed. Therefore, a semiconductor memory device having excellent characteristics including the two-dimensional NOR memory 100 can be realized.

From the viewpoint of effectively recovering imprinting occurring in the memory cell MC, the absolute value of the first recovery voltage Vrp1 is preferably equal to or more than the absolute value of the erase voltage Verase. From the same viewpoint, the fourth pulse width w4 of the first recovery voltage pulse RP1 is preferably equal to or more than the third pulse width w3 of the second write voltage pulse WP2. From the same viewpoint, the fourth pulse width w4 is preferably equal to or more than the second pulse width w2 of the erase voltage pulse EP.

From the viewpoint of effectively recovering imprinting occurring in the memory cell MC, the absolute value of the second recovery voltage Vrp2 is preferably equal to or more than the absolute value of the first write voltage Vwrite1. From the same viewpoint, the fifth pulse width w5 of the second recovery voltage pulse RP2 is preferably equal to or more than the third pulse width w3 of the second write voltage pulse WP2. From the same viewpoint, the fifth pulse width w5 is preferably equal to or more than the first pulse width w1 of the first write voltage pulse WP1.

As described above, according to the second embodiment and the modification, imprinting of a memory cell is effectively recovered, and a semiconductor memory device having excellent characteristics can be realized.

### Third Embodiment

A semiconductor memory device of a third embodiment includes: a memory cell array including a first semiconductor layer extending in a first direction, a plurality of gate electrode layers stacked in the first direction, a first wiring electrically connected to the first semiconductor layer, a second wiring electrically connected to the first semiconductor layer, and a plurality of first memory cells, each of the first memory cells including the first semiconductor layer, one gate electrode layer of the gate electrode layers, and a gate insulating layer containing a ferroelectric and provided between the first semiconductor layer and the one gate electrode layer; and a control circuit configured to control the first memory cells. The control circuit is capable of executing a first write operation to one first memory cell selected from the first memory cells. The first write operation is to apply a first voltage pulse having a first voltage with a first polarity and a first pulse width between the one gate electrode layer of the one first memory cell and at least one of the first wiring and the second wiring. The control circuit is capable of executing an erase operation to the one first memory cell. The erase operation is to apply a second voltage pulse having a second voltage with a second polarity opposite the first polarity and a second pulse width between the one gate electrode layer of the one first memory cell and at least one of the first wiring and the second wiring. The control circuit is capable of executing a second write operation to the one first memory cell. The second write operation is to apply a third voltage pulse having a third voltage with the first polarity having a smaller absolute value than an absolute value of the first voltage and a third pulse width between the one gate electrode layer of the one first memory cell and at least one of the first wiring and the second wiring. The control circuit is capable of executing a first operation to the one first memory cell before the second write operation, the first operation being consecutive with the second write operation. The first operation is to apply a fourth voltage pulse having a fourth voltage with the first polarity having a larger absolute value than the absolute value of the third voltage and a fourth pulse width and apply a fifth voltage pulse having a fifth voltage with the second polarity having a larger absolute value than the absolute value of the third voltage and a fifth pulse width between the one gate electrode layer of the one first memory cell and at least one of the first wiring and the second wiring, the applying of the fifth voltage pulse being consecutive with the applying of the fourth voltage pulse.

The semiconductor memory device of the third embodiment is different from the semiconductor memory device of the first embodiment in that a three-dimensional NAND flash memory is included instead of the two-dimensional NOR memory. Hereinafter, description of contents overlapping with the first embodiment may be partially omitted.

The semiconductor memory device of the third embodiment includes a three-dimensional NAND flash memory. The semiconductor memory device of the third embodiment uses, as the memory cell, a field effect transistor containing a ferroelectric in a gate insulating layer. The semiconductor memory device of the third embodiment is a multi-level memory in which one memory cell can hold three or more levels.

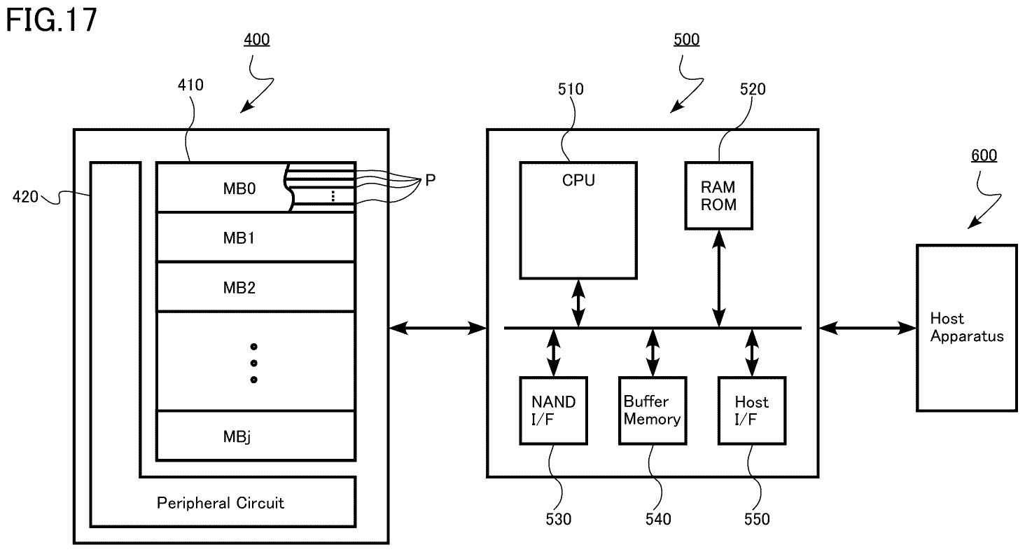

FIG. 17 is a block diagram of a memory system including a semiconductor memory device of a third embodiment. The memory system of the third embodiment includes, for example, a three-dimensional NAND flash memory 400, a controller 500, and a host apparatus 600. The semiconductor memory device of the third embodiment includes, for example, the three-dimensional NAND flash memory 400 and the controller 500.

The three-dimensional NAND flash memory 400 is, for example, a three-dimensional NAND flash memory chip. The controller 500 is, for example, a controller chip. The three-dimensional NAND flash memory 400 and the controller 500 are, for example, a memory card in which the two are implemented in combination, or a solid state drive (SSD) in which the two are implemented in combination.

The three-dimensional NAND flash memory 400 and the controller 500 may be provided in the same semiconductor chip, for example.

The host apparatus 600 is, for example, a digital camera or a personal computer.

As illustrated in FIG. 17, the three-dimensional NAND flash memory 400 includes a memory cell array 410 and a peripheral circuit 420.

The memory cell array 410 includes a plurality of memory blocks MB0 to MBj (j is a natural number). Each of the plurality of memory blocks MB0 to MBj includes a plurality of pages P. In the third embodiment, a data write operation and a data read operation are performed, for example, by using a page P as one unit. In the third embodiment, the data erase operation is performed, for example, using a memory block MBi (i is a natural number equal to or less than j) as one unit.

The peripheral circuit 420 is provided around the memory cell array 410. The peripheral circuit 420 has, for example, a function of controlling the operation of the memory cell array 410 according to an instruction received from the controller 500. The peripheral circuit 420 executes, for example, the data write operation or data read operation for the page P designated by the controller 500. The peripheral circuit 420 executes, for example, the data erase operation for the memory block MBi designated by the controller 500. The peripheral circuit 420 executes, for example, the recovery operation for the memory block MBi designated by the controller 500.

The controller 500 controls the three-dimensional NAND flash memory 400. The controller 500 accesses the three-dimensional NAND flash memory 400 in response to an instruction received from the host apparatus 600.

The peripheral circuit 420 of the three-dimensional NAND flash memory 400 and the controller 500 are examples of the control circuit of the third embodiment.

As illustrated in FIG. 17, the controller 500 includes a processor 510 (CPU), a built-in memory 520 (RAM, ROM), a NAND interface circuit 530, a buffer memory 540, and a host interface circuit 550.

The processor 510 controls the overall operation of the controller 500. The processor 510 has a function of executing various processes for managing the three-dimensional NAND flash memory 400.

The built-in memory 520 is, for example, a semiconductor memory. The built-in memory 520 is used, for example, as a work area for the processor. The built-in memory 520 stores, for example, firmware for managing the three-dimensional NAND flash memory 400 and various management tables.

The NAND interface circuit 530 is connected to the three-dimensional NAND flash memory 400 via a NAND bus. The NAND interface circuit 530 has a function of controlling communication with the three-dimensional NAND flash memory 400.

The buffer memory 540 has, for example, a function of temporarily storing data written into memory cells or data read from memory cells.

The host interface circuit 550 is connected to the host apparatus 600 via a host bus. The host interface circuit 550 transmits, for example, an instruction received from the host apparatus 600 to the processor 510. The host interface circuit 550 transmits, for example, data received from the host apparatus 600 to the buffer memory 540. The host interface circuit 550 transmits, for example, data in the buffer memory 540 to the host apparatus 600 in response to an instruction from the processor 510.

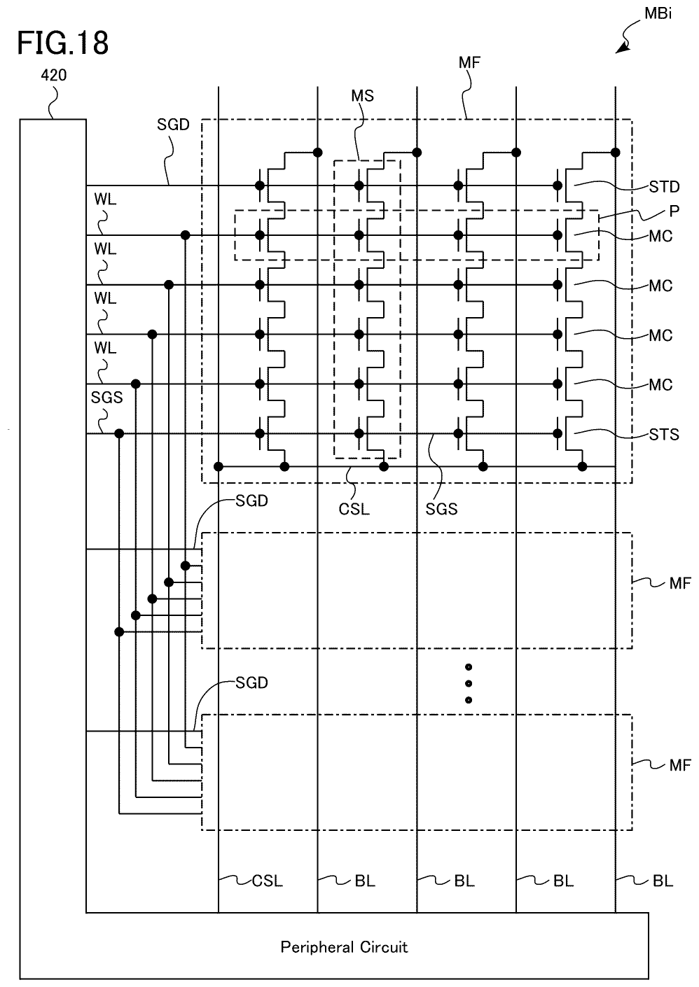

FIG. 18 is an equivalent circuit diagram of memory blocks of the semiconductor memory device of the third embodiment. FIG. 18 is an equivalent circuit diagram of the memory block MBi of the three-dimensional NAND flash memory 400.

The memory block MBi is connected to the peripheral circuit 420 by a common source line CSL, a plurality of bit lines BL, a plurality of word lines WL, a source selection gate line SGS, and a drain selection gate line SGD.

The memory block MBi includes a plurality of memory fingers MF. Each memory finger MF includes a plurality of memory strings MS.

One end of each of the plurality of memory strings MS is connected to the common source line CSL. The other end of each of the plurality of memory strings MS is connected to the bit line BL.

Each of the plurality of memory strings MS includes a source selection transistor STS, a plurality of memory cells MC, and a drain selection transistor STD connected in series between the common source line CSL and the bit line BL. The source selection transistor STS, the plurality of memory cells MC, and the drain selection transistor STD are field effect transistors (FETs) whose operations are controlled by voltages applied to their gate electrodes.

The word line WL is connected to the gate electrode of each of the plurality of memory cells MC. The word line WL is commonly connected to all memory strings MS in one memory finger MF. In one memory block MBi, a plurality of word lines WL connected to one memory finger MF are commonly connected to a plurality of word lines connected to the remaining memory fingers MF. In one memory finger MF, a plurality of memory cells MC commonly connected to one word line WL form the page P.

The source selection gate line SGS is connected to the gate electrode of the source selection transistor STS. The drain selection gate line SGD is connected to the gate electrode of the drain selection transistor STD.

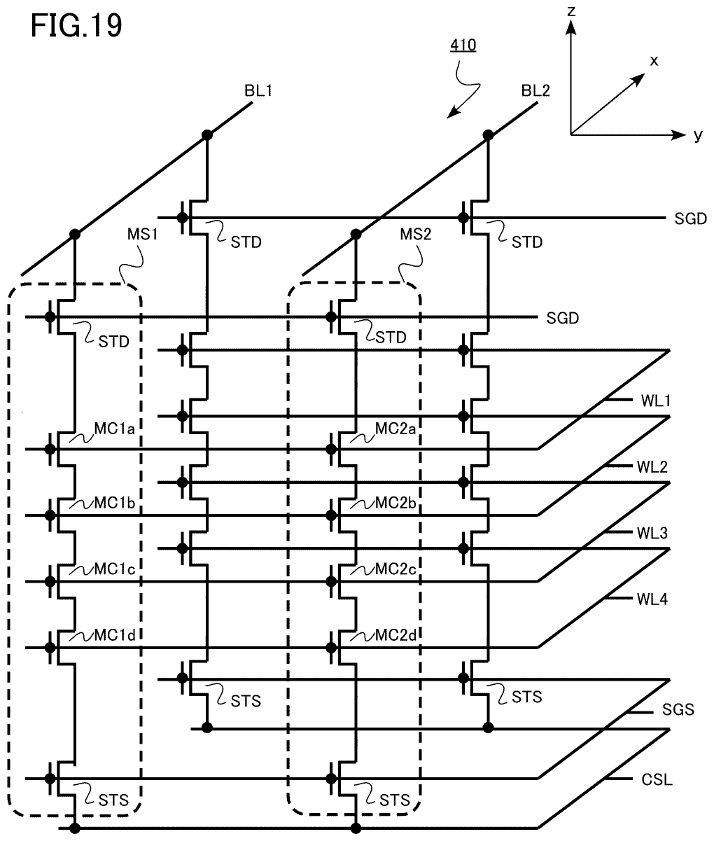

FIG. 19 is an equivalent circuit diagram of a part of a memory cell array of the semiconductor memory device of the third embodiment. FIG. 19 is an equivalent circuit diagram of a part of the memory cell array 410 of the three-dimensional NAND flash memory 400. FIG. 19 is an equivalent circuit diagram of a part of the memory block MBi of the three-dimensional NAND flash memory 400.

The plurality of word lines WL are arranged in a z direction so as to be spaced from each other. The plurality of word lines WL are stacked and arranged in the z direction. The plurality of word lines WL include a first word line WL1, a second word line WL2, a third word line WL3, and a fourth word line WL4.

The plurality of bit lines BL extend in an x direction, for example. The plurality of bit lines BL includes a first bit line BL1 and a second bit line BL2.

The plurality of memory strings MS extend in the z direction. The plurality of memory strings MS includes a first memory string MS1 and a second memory string MS2.

The first memory string MS1 is connected to the first bit line BL1. The second memory string MS2 is connected to the second bit line BL2.

Hereinafter, the x direction is defined as a third direction, the y direction is defined as a second direction, and the z direction is defined as a first direction. The x direction, the y direction, and the z direction cross each other, and for example, are perpendicular to each other.

As illustrated in FIG. 19, the memory string MS includes the source selection transistor STS, a plurality of memory cells MC, and the drain selection transistor STD connected in series between the common source line CSL and the bit line BL. The memory string MS is electrically connected to the common source line CSL and the bit line BL. The common source line CSL is an example of the first wiring. The bit line BL is an example of the second wiring or the third wiring.

The first memory string MS1 includes, for example, a plurality of first memory cells MC1a, MC1b, MC1c, and MC1d. The second memory string MS2 includes, for example, a plurality of second memory cells MC2a, MC2b, MC2c, and MC2d.

Although FIG. 19 illustrates a case where the number of memory cells MC included in one memory string MS is 4, the number of memory cells MC is not limited to 4. The number of memory cells MC may be equal to or less than 3 or may be equal to or more than 5.

One memory string MS can be selected by selecting one bit line BL and one drain selection gate line SGD, and one memory cell MC can be selected by selecting one word line WL. The word line WL is a gate electrode of a memory cell transistor constituting the memory cell MC.

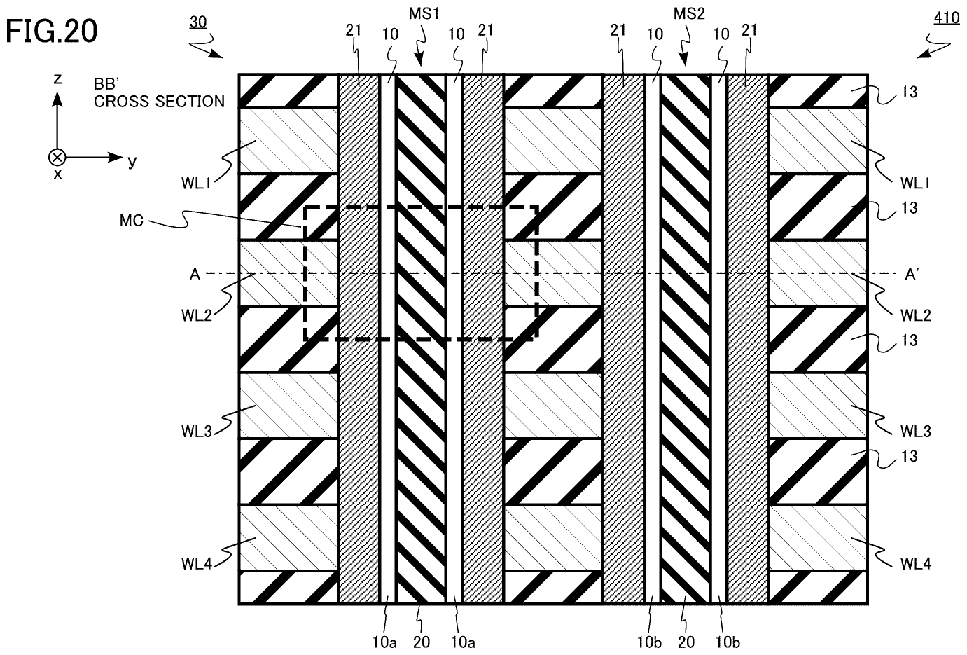

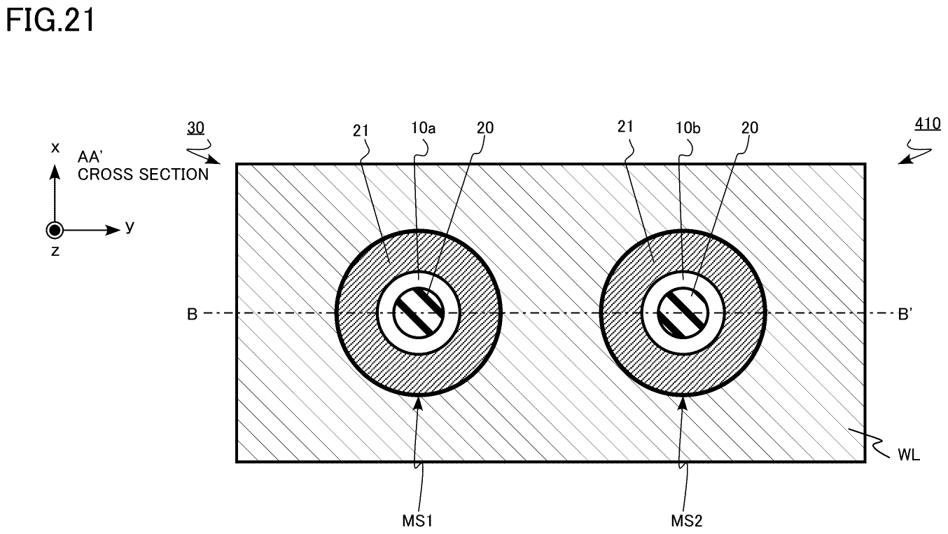

FIGS. 20 and 21 are schematic cross-sectional views of a part of the memory cell array of the semiconductor memory device of the third embodiment. FIGS. 20 and 21 illustrate cross sections of a plurality of memory cells MC in the first memory string MS1 and the second memory string MS2 in the memory cell array 410 of FIG. 19.

FIG. 20 is a yz cross-sectional view of the memory cell array 410. FIG. 20 is a cross section taken along the line BB′ of FIG. 21. FIG. 21 is an xy cross-sectional view of the memory cell array 410. FIG. 21 is a cross section taken along the line AA′ of FIG. 20. In FIG. 20, the region surrounded by the broken line is one memory cell MC.

As illustrated in FIGS. 20 and 21, the memory cell array 410 includes a word line WL, a semiconductor layer 10, a gate insulating layer 21, an interlayer insulating layer 13, and a core insulating region 20. A plurality of word lines WL and a plurality of interlayer insulating layers 13 constitute a stacked body 30.

The word line WL is an example of the gate electrode layer.

The memory cell array 110 is, for example, provided on a semiconductor substrate (not illustrated). The semiconductor substrate has, for example, a surface parallel to the x and y direction.

The word line WL and the interlayer insulating layer 13 are alternately stacked in the z direction on the semiconductor substrate. The word lines WL are repeatedly arranged in the z direction so as to be spaced from each other. The word line WL functions as a control electrode of a memory cell transistor.

The word line WL is, for example, a plate-shaped conductor. The word line WL is, for example, a metal.

The interlayer insulating layer 13 is provided in the z direction of the word line WL. The word line WL and the interlayer insulating layer 13 are repeatedly arranged in the z direction.

The interlayer insulating layer 13 separates the word line WL and the word line WL from each other. The interlayer insulating layer 13 electrically separates the word line WL and the word line WL from each other.

The interlayer insulating layer 13 is, for example, an oxide, an oxynitride, or a nitride. The interlayer insulating layer 13 is, for example, silicon oxide.

The semiconductor layer 10 is provided in the stacked body 30. The semiconductor layer 10 extends in the z direction. The semiconductor layer 10 extends in a direction perpendicular to the surface of the semiconductor substrate.

The semiconductor layer 10 is provided so as to penetrate the stacked body 30. The semiconductor layer 10 is surrounded by the plurality of word lines WL. The semiconductor layer 10 has, for example, a cylindrical shape. The semiconductor layer 10 functions as a channel of the memory cell transistor.

The semiconductor layer 10 is, for example, a polycrystalline semiconductor. The semiconductor layer 10 is, for example, polycrystalline silicon.

The semiconductor layer 10 includes, for example, a first semiconductor layer 10a and a second semiconductor layer 10b.

The semiconductor layer 10 is electrically connected to the common source line CSL and the bit line BL. The first semiconductor layer 10a and the second semiconductor layer 10b are electrically connected to the common source line CSL and the bit line BL.

The common source line CSL is an example of the first wiring. The bit line BL is an example of the second wiring or the third wiring. For example, the first bit line BL1 electrically connected to the first semiconductor layer 10a is an example of the second wiring. For example, the second bit line BL2 electrically connected to the second semiconductor layer 10b is an example of the third wiring.

The gate insulating layer 21 is provided between the semiconductor layer 10 and the word line WL and contains a ferroelectric. The gate insulating layer 21 is, for example, a ferroelectric layer.

The gate insulating layer 21 contains, for example, at least one element selected from the group consisting of hafnium (Hf) and zirconium (Zr), and oxygen.

The gate insulating layer 21 is, for example, polycrystalline. The gate insulating layer 11 contains, for example, a crystal having one space group selected from the group consisting of a space group Pca21 (space group number 29), a space group R3 (space group number 146), a space group R3m (space group number 160), and Pmn21 (space group number 31). An oxide of hafnium (Hf) or zirconium (Zr) having a space group Pca21 (space group number 29), space group R3 (space group number 146), space group R3m (space group number 160), or Pmn21 (space group number 31) is a ferroelectric.

The core insulating region 20 is provided in the stacked body 30. The core insulating region 20 extends in the z direction. The core insulating region 20 is provided so as to penetrate the stacked body 30. The core insulating region 20 is surrounded by the semiconductor layer 10. The core insulating region 20 is surrounded by the plurality of word lines WL. The core insulating region 20 has a columnar shape. The core insulating region 20 has, for example, a cylindrical shape.

The core insulating region 20 is, for example, an oxide, an oxynitride, or a nitride. The core insulating region 20 contains, for example, silicon (Si) and oxygen (O). The core insulating region 20 is, for example, silicon oxide.

The peripheral circuit 420 of the three-dimensional NAND flash memory 400 and the controller 500 control, for example, the plurality of memory cells MC in the memory cell array 410. The peripheral circuit 420 of the three-dimensional NAND flash memory 400 and the controller 500 control, for example, writing of data to a memory cell included in the memory cell array 410, reading of data from the memory cell, or erasing data in the memory cell.

The peripheral circuit 420 of the three-dimensional NAND flash memory 400 and the controller 500, for example, the peripheral circuit 420 and the controller 500 control the first memory cells MC1a to MC1d included in the first memory string MS1. For example, the peripheral circuit 420 and the controller 500 control the second memory cells MC2a to MC2d included in the second memory string MS2.

A possible level of the memory cell MC of the semiconductor memory device of the third embodiment is the same as in the first embodiment described with reference to FIG. 4.

The peripheral circuit 420 and the controller 500 are capable of executing the first write operation, the erase operation, the second write operation, and the suppression operation consecutive with the second write operation before the second write operation to any one first memory cell MC1 selected from the first memory cells MC1a to MC1d, for example. The voltage pulses applied to the memory cell MC in the first write operation, the second write operation, the erase operation, and the suppression operation in the control of the semiconductor memory device of the third embodiment are the same as in the semiconductor memory device of the first embodiment. The suppression operation is an example of the first operation.

For example, when the first write operation, the erase operation, the second write operation, and the suppression operation are performed on the first memory cell MC1a, the first word line WL1 is an example of the gate electrode layer, the common source line CSL is an example of the first wiring, and the first bit line BL1 is an example of the second wiring. Hereinafter, a case where the first write operation, the erase operation, the second write operation, and the suppression operation are performed on the first memory cell MC1a will be described as an example.

The first write operation is to apply the first write voltage pulse WP1 between the first word line WL1 of the first memory cell MC1a and at least one of the common source line CSL and the first bit line BL1. The first write operation is to apply the first write voltage pulse WP1 to the gate insulating layer 21 of the first memory cell MC1a.

The first write voltage pulse WP1 has a first write voltage Vwrite1 with a first polarity and a first pulse width w1. The first write voltage pulse WP1 is an example of the first voltage pulse. The first write voltage Vwrite1 is an example of the first voltage.

The erase operation is to apply an erase voltage pulse EP between the first word line WL1 of the first memory cell MC1a and at least one of the common source line CSL and the first bit line BL1. The erase operation is, for example, to apply the erase voltage pulse EP to the gate insulating layer 21 of the first memory cell MC1a. The erase voltage pulse EP has an erase voltage Verase with a second polarity opposite to the first polarity and a second pulse width w2. The erase voltage pulse EP is an example of the second voltage pulse. The erase voltage Verase is an example of the second voltage.

The second write operation is to apply the second write voltage pulse WP2 between the first word line WL1 of the first memory cell MC1a and at least one of the common source line CSL and the first bit line BL1. The second write operation is to apply the second write voltage pulse WP2 to the gate insulating layer 21 of the first memory cell MC1a.

The second write voltage pulse WP2 has a second write voltage Vwrite2 with the first polarity and a third pulse width w3. The second write voltage pulse WP2 is an example of the third voltage pulse. The second write voltage Vwrite2 is an example of the third voltage.

The suppression operation is to apply a first suppression voltage pulse SP1 and a second suppression voltage pulse SP2 between the first word line WL1 of the first memory cell MC1a and at least one of the common source line CSL and the first bit line BL1. The suppression operation is to apply the first suppression voltage pulse SP1 and the second suppression voltage pulse SP2 to the gate insulating layer 21 of the first memory cell MC1a.

The first suppression voltage pulse SP1 has a first suppression voltage Vsup1 with the first polarity and a fourth pulse width w4. The first suppression voltage pulse SP1 is an example of the fourth voltage pulse. The first suppression voltage Vsup1 is an example of the fourth voltage.

The second suppression voltage pulse SP2 has a second suppression voltage Vsup2 with the second polarity and a fifth pulse width w5. The second suppression voltage pulse SP2 is an example of the fifth voltage pulse. The second suppression voltage Vsup2 is an example of the fifth voltage.

For example, the first polarity is a polarity in which the word line WL has a positive voltage with respect to the common source line CSL or the bit line BL, and the second polarity is a polarity in which the word line WL has a negative voltage with respect to the common source line CSL or the bit line BL. In other words, for example, the first polarity is a polarity in which the word line WL has a positive voltage with respect to the semiconductor layer 10, and the second polarity is a polarity in which the word line WL has a negative voltage with respect to the semiconductor layer 10.

Similarly to the semiconductor memory device of the first embodiment, the semiconductor memory device of the third embodiment can cause polarization inversion in all polarization domains of the memory cell MC by performing the suppression operation before the second write operation. Therefore, imprinting of the memory cell MC is suppressed, and a write failure or an erase failure of the memory cell MC is suppressed. Therefore, a semiconductor memory device having excellent characteristics including the three-dimensional NAND flash memory 400 can be realized.

### Modification

A modification of the semiconductor memory device of the third embodiment is different from the semiconductor memory device of the third embodiment in that the second write operation is to apply a third voltage pulse having a third voltage with the second polarity having a smaller absolute value than an absolute value of the second voltage and a third pulse width between the gate electrode layer and at least one of the first wiring and the second wiring, and the first operation is to apply a fourth voltage pulse having a fourth voltage with the second polarity having a larger absolute value than the absolute value of the third voltage and a fourth pulse width and apply a fifth voltage pulse having a fifth voltage with the first polarity having a larger absolute value than the absolute value of the third voltage and a fifth pulse width between the gate electrode layer and at least one of the first wiring and the second wiring, the applying of the fifth voltage pulse being consecutive with the applying of the fourth voltage pulse.

A possible level of the memory cell MC of the modification of the semiconductor memory device of the third embodiment is the same as in the modification of the first embodiment described with reference to FIG. 8. The voltage pulses applied to the memory cell MC in the first write operation, the second write operation, the erase operation, and the suppression operation in the control of the modification of the semiconductor memory device of the third embodiment are the same as in the semiconductor memory device of the modification of the first embodiment.

Similarly to the modification of the semiconductor memory device of the first embodiment, the modification of the semiconductor memory device of the third embodiment can cause polarization inversion in all polarization domains of the memory cell MC by performing the suppression operation before the second write operation. Therefore, imprinting of the memory cell MC is suppressed, and a write failure or an erase failure of the memory cell MC is suppressed. Therefore, a semiconductor memory device having excellent characteristics including the three-dimensional NAND flash memory 400 can be realized.

As described above, according to the third embodiment and the modification, imprinting of a memory cell is suppressed, and a semiconductor memory device having excellent characteristics can be realized.

### Fourth Embodiment

A semiconductor memory device of a fourth embodiment includes: a memory cell array including a first semiconductor layer extending in a first direction, a second semiconductor layer extending in the first direction, a plurality of gate electrode layers stacked in the first direction, a first wiring electrically connected to the first semiconductor layer and the second semiconductor layer, a second wiring electrically connected to the first semiconductor layer, a third wiring electrically connected to the second semiconductor layer, a plurality of first memory cells, each of the first memory cells including the first semiconductor layer, one gate electrode layer of the gate electrode layers, and a gate insulating layer containing a ferroelectric and provided between the first semiconductor layer and the one gate electrode layer, and a plurality of second memory cells, each of the second memory cells including the second semiconductor layer, one gate electrode layer of the gate electrode layers, and a gate insulating layer containing a ferroelectric and provided between the second semiconductor layer and the one gate electrode layer; and a control circuit configured to control the first memory cells and the second memory cells. The control circuit is capable of executing a first write operation to any one memory cell of the first memory cells and the second memory cells. The first write operation is to apply a first voltage pulse having a first voltage with a first polarity and a first pulse width between the one gate electrode layer of the one memory cell and at least one of the first wiring and the second wiring when the one memory cell is one of the first memory cells. The first write operation is to apply a first voltage pulse having a first voltage with a first polarity and a first pulse width between the one gate electrode layer of the one memory cell and at least one of the first wiring and the third wiring when the one memory cell is one of the second memory cells. The control circuit is capable of executing an erase operation to the first memory cells and the second memory cells. The erase operation is to apply a second voltage pulse having a second voltage with a second polarity opposite to the first polarity and a second pulse width between the gate electrode layers and the first wiring. The control circuit is capable of executing a second write operation to the one memory cell. The second write operation is to apply a third voltage pulse having a third voltage with the first polarity having a smaller absolute value than an absolute value of the first voltage and a third pulse width between the one gate electrode layer of the one memory cell and at least one of the first wiring and the second wiring when the one memory cell is one of the first memory cells. The second write operation is to apply a third voltage pulse having a third voltage with the first polarity having a smaller absolute value than an absolute value of the first voltage and a third pulse width between the one gate electrode layer of the one memory cell and at least one of the first wiring and the third wiring when the one memory cell is one of the second memory cells. The control circuit is capable of determining whether or not the number of times of execution of the second write operation to each of the plurality of first memory cells and the plurality of second memory cells has reached a predetermined first number of times. The control circuit is capable of executing the first operation to a plurality of first memory cells and a plurality of second memory cells when it is determined that the number of times of execution to any one of the plurality of first memory cells and the plurality of second memory cells has reached the predetermined first number of times. The first operation is to apply a fourth voltage pulse having a fourth voltage with the first polarity having a larger absolute value than the absolute value of the third voltage and a fourth pulse width and apply a fifth voltage pulse having a fifth voltage with the second polarity having a larger absolute value than the absolute value of the third voltage and a fifth pulse width between the plurality of gate electrode layers and the first wiring, the applying of the fifth voltage pulse being consecutive with the applying of the fourth voltage pulse.

The semiconductor memory device of the fourth embodiment is different from the semiconductor memory device of the third embodiment in that a recovery operation is performed. Hereinafter, description of contents overlapping with the third embodiment may be partially omitted.

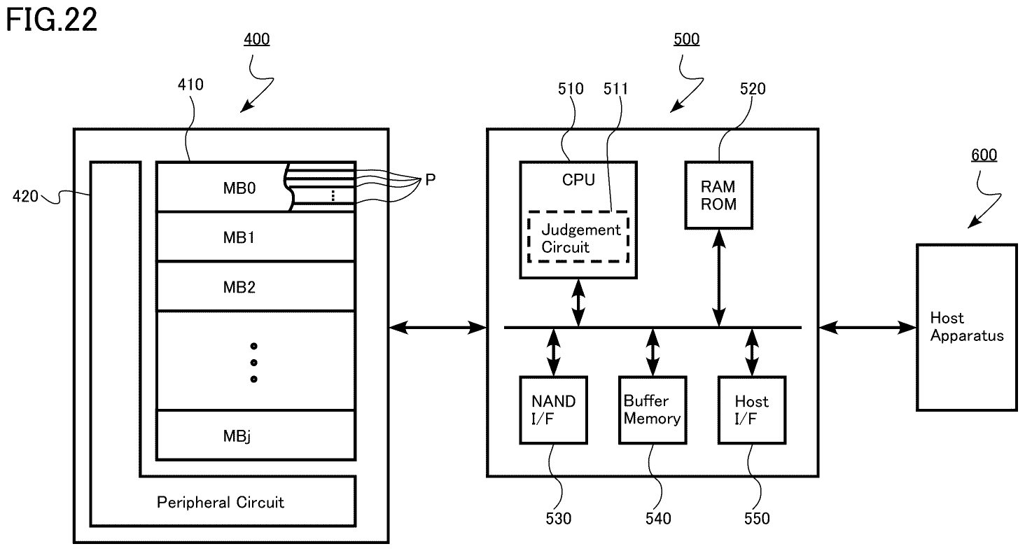

FIG. 22 is a block diagram of a memory system including a semiconductor memory device of a fourth embodiment. The processor 510 of the fourth embodiment includes a judgement circuit 511 unlike the processor 510 of the third embodiment.

The built-in memory 520 stores, for example, the number of times of execution of the second write operation executed to each of the memory cells included in the three-dimensional NAND flash memory 400. The built-in memory 520 stores, for example, a predetermined first number of times of the second write operation serving as a criterion for determining whether or not to execute the recovery operation. The judgement circuit 511 is capable of determining whether or not the number of times of execution of the second write operation to any memory cell has reached the predetermined number of times on the basis of the number of times of execution of the second write operation and the predetermined first number of times of the second write operation stored in the built-in memory 520.

The peripheral circuit 420 and the controller 500 are capable of measuring and storing the number of times of execution of the second write operation to each of the first memory cells MC1a to MC1d and the second memory cells MC2a to MC2d, for example. The peripheral circuit 420 and the controller 500 are capable of determining whether or not the number of times of execution of the second write operation to each of the first memory cells MC1a to MC1d and the second memory cells MC2a to MC2d has reached a predetermined first number of times. The peripheral circuit 420 and the controller 500 are capable of executing the recovery operation to first memory cells MC1a to MC1d and second memory cells MC2a to MC2d when it is determined that the number of times of execution to any one of the first memory cells MC1a to MC1d and the second memory cells MC2a to MC2d has reached the predetermined first number of times. The recovery operation is an example of the first operation.

A possible level of the memory cell MC of the semiconductor memory device of the fourth embodiment is the same as in the first embodiment described with reference to FIG. 4.

The peripheral circuit 420 and the controller 500 are capable of executing the first write operation and the second write operation to any one memory cell MC selected from the first memory cells MC1a to MC1d and the second memory cells MC2a to MC2b, for example. The peripheral circuit 420 and the controller 500 are capable of executing the erase operation and the recovery operation to all the memory cells MC of the first memory cells MC1a to MC1d and the second memory cells MC2a to MC2b.

The voltage pulses applied to the memory cell MC in the first write operation, the second write operation, the erase operation, and the recovery operation in the control of the semiconductor memory device of the fourth embodiment are the same as in the semiconductor memory device of the second embodiment.

For example, when the first write operation and the second write operation are performed on the first memory cell MC1a, the first word line WL1 is an example of the gate electrode layer, the common source line CSL is an example of the first wiring, and the first bit line BL1 is an example of the second wiring. When the first write operation and the second write operation are performed on the second memory cell MC2c, the third word line WL3 is an example of the gate electrode layer, the common source line CSL is an example of the first wiring, and the second bit line BL2 is an example of the third wiring. Hereinafter, a case where the first write operation and the second write operation are performed on the first memory cell MC1a or the second memory cell MC2c will be described as an example.

The first write operation is to apply the first write voltage pulse WP1 between the first word line WL1 and at least one of the common source line CSL and the first bit line BL1 when the first write operation is executed to the first memory cell MC1a. The first write operation is to apply the first write voltage pulse WP1 to the gate insulating layer 21 of the first memory cell MC1a.

The first write operation is to apply the first write voltage pulse WP1 between the third word line WL3 and at least one of the common source line CSL and the second bit line BL2 when the first write operation is executed to the second memory cell MC2c. The first write operation is to apply the first write voltage pulse WP1 to the gate insulating layer 21 of the second memory cell MC2c.

The first write voltage pulse WP1 has a first write voltage Vwrite1 with a first polarity and a first pulse width w1. The first write voltage pulse WP1 is an example of the first voltage pulse. The first write voltage Vwrite1 is an example of the first voltage.

The erase operation is to apply the erase voltage pulse EP between the first word line WL1, the second word line WL2, the third word line WL3, and the fourth word line WL4 and common source line CSL. The erase operation is, for example, to apply the erase voltage pulse EP to the gate insulating layers 21 of the first memory cells MC1a to MC1d and the second memory cells MC2a to MC2d.

The erase voltage pulse EP has an erase voltage Verase with a second polarity opposite to the first polarity and a second pulse width w2. The erase voltage pulse EP is an example of the second voltage pulse. The erase voltage Verase is an example of the second voltage.

The second write operation is to apply the second write voltage pulse WP2 between the first word line WL1 and at least one of the common source line CSL and the first bit line BL1 when the second write operation is executed to the first memory cell MC1a. The second write operation is to apply the second write voltage pulse WP2 to the gate insulating layer 21 of the first memory cell MC1a.

The second write operation is to apply the second write voltage pulse WP2 between the third word line WL3 and at least one of the common source line CSL and the second bit line BL2 when the second write operation is executed to the second memory cell MC2c. The second write operation is to apply the second write voltage pulse WP2 to the gate insulating layer 21 of the second memory cell MC2c.

The second write voltage pulse WP2 has a second write voltage Vwrite2 with the first polarity and a third pulse width w3. The second write voltage pulse WP2 is an example of the third voltage pulse. The second write voltage Vwrite2 is an example of the third voltage.

The recovery operation is to apply the first recovery voltage pulse RP1 and the second recovery voltage pulse RP2 between the first word line WL1, the second word line WL2, the third word line WL3, and the fourth word line WL4 and the common source line CSL. The recovery operation is to apply the first recovery voltage pulse RP1 and the second recovery voltage pulse RP2 to the gate insulating layers 21 of the first memory cells MC1a to MC1d and the second memory cells MC2a to MC2d.

The first recovery voltage pulse RP1 has a first recovery voltage Vrp1 with the first polarity and a fourth pulse width w4. The first recovery voltage pulse RP1 is an example of the fourth voltage pulse. The first recovery voltage Vrp1 is an example of the fourth voltage.

The second recovery voltage pulse RP2 has a second recovery voltage Vrp2 with the second polarity and a fifth pulse width w5. The second recovery voltage pulse RP2 is an example of the fifth voltage pulse. The second recovery voltage Vrp2 is an example of the fifth voltage.

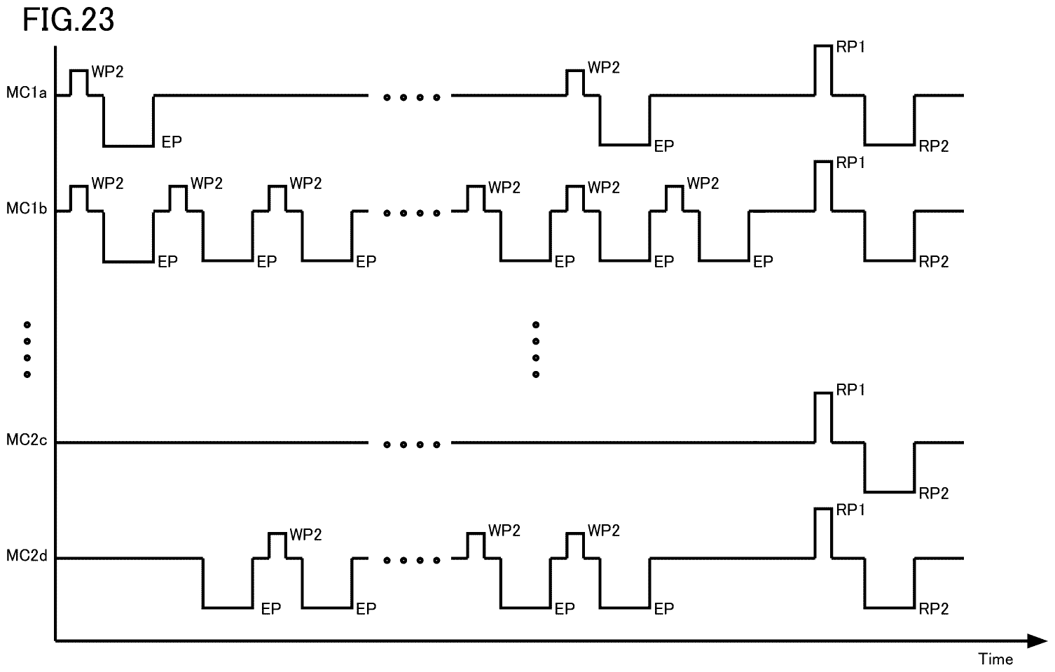

FIG. 23 is a timing chart describing a control method of the semiconductor memory device of the fourth embodiment. FIG. 23 illustrates a voltage pulse applied to the first memory cells MC1a to MC1d and the second memory cells MC2a to MC2d included in the memory cell array 410.

As illustrated in FIG. 23, for example, it is assumed that the number of times of execution to the first memory cell MC1b has reached the predetermined first number of times among the number of times of execution of the second write operation to each of the first memory cells MC1a to MC1d and the second memory cells MC2a to MC2d. In this case, the recovery operation is collectively executed to all of the first memory cells MC1a to MC1d and the second memory cells MC2a to MC2d.

Similarly to the second embodiment, the semiconductor memory device of the fourth embodiment performs a recovery operation for recovering the imprinting of the memory cell MC when the second write operation for accelerating the imprinting of the memory cell MC reaches the predetermined first number of times. Therefore, imprinting of the memory cell MC is effectively recovered, and a write failure or an erase failure of the memory cell MC is suppressed. Therefore, a semiconductor memory device having excellent characteristics including the three-dimensional NAND flash memory 400 can be realized.

### Modification

A modification of the semiconductor memory device of the fourth embodiment is different from the semiconductor memory device of the fourth embodiment in that the second write operation is to apply s third voltage pulse having a third voltage with the second polarity having a smaller absolute value than an absolute value of the second voltage and a third pulse width, and the first operation is to apply a fourth voltage pulse having a fourth voltage with the second polarity having a larger absolute value than the absolute value of the third voltage and a fourth pulse width and apply a fifth voltage pulse having a fifth voltage with the first polarity having a larger absolute value than the absolute value of the third voltage and a fifth pulse width between the gate electrode layer and the first wiring, the applying of the fifth voltage pulse being consecutive with the applying of the fourth voltage pulse.

A possible level of the memory cell MC of the modification of the semiconductor memory device of the fourth embodiment is the same as in the modification of the first embodiment described with reference to FIG. 8. The voltage pulses applied to the memory cell MC in the first write operation, the second write operation, the erase operation, and the recovery operation in the control of the modification of the semiconductor memory device of the fourth embodiment are the same as in the semiconductor memory device of the modification of the second embodiment.

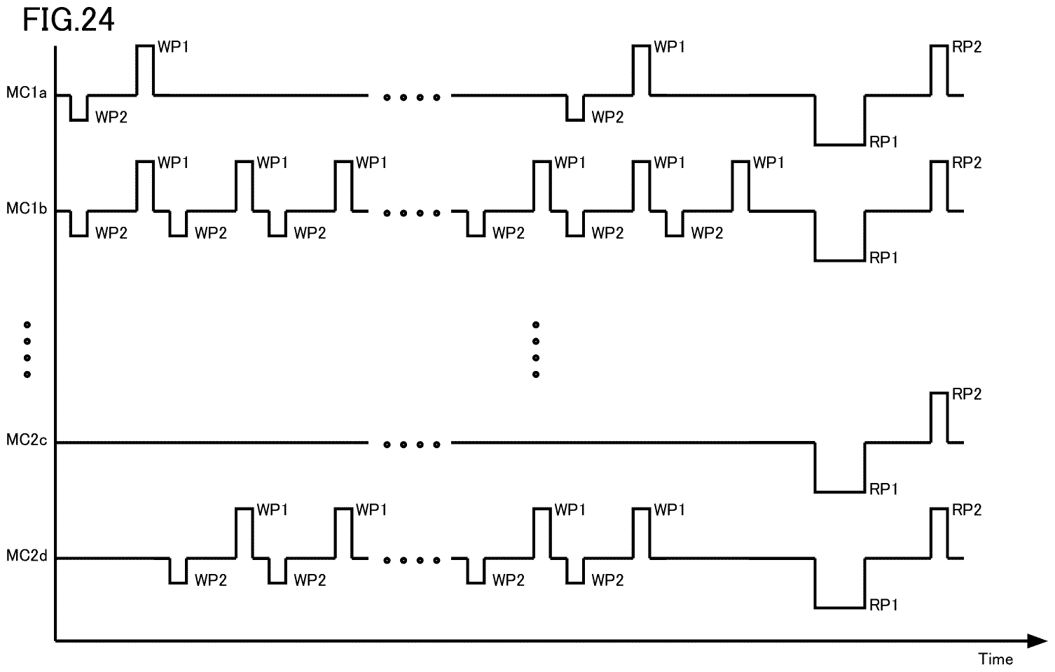

FIG. 24 is a timing chart describing a control method of a modification of the semiconductor memory device of the fourth embodiment. FIG. 24 illustrates a voltage pulse applied to the first memory cells MC1a to MC1d and the second memory cells MC2a to MC2d included in the memory cell array 410.

As illustrated in FIG. 24, for example, when the number of times of execution of the second write operation to the first memory cell MC1b has reached the predetermined first number of times, the recovery operation is collectively executed to all of the first memory cells MC1a to MC1d and the second memory cells MC2a to MC2d.

Similarly to the modification of the second embodiment, the modification of the semiconductor memory device of the fourth embodiment performs a recovery operation for recovering the imprinting of the memory cell MC when the second write operation for accelerating the imprinting of the memory cell MC reaches the predetermined first number of times. Therefore, imprinting of the memory cell MC is effectively recovered, and a write failure or an erase failure of the memory cell MC is suppressed. Therefore, a semiconductor memory device having excellent characteristics including the three-dimensional NAND flash memory 400 can be realized.

As described above, according to the fourth embodiment and the modification, imprinting of a memory cell is effectively recovered, and a semiconductor memory device having excellent characteristics can be realized.

### Fifth Embodiment

A semiconductor memory device of a fifth embodiment includes: a memory cell including a semiconductor layer, a gate electrode layer, a gate insulating layer provided between the semiconductor layer and the gate electrode layer, a first conductive layer electrically connected to the semiconductor layer, a second conductive layer, and a capacitor insulating layer containing a ferroelectric and provided between the first conductive layer and the second conductive layer; a first wiring electrically connected to the first conductive layer via the semiconductor layer and a second wiring electrically connected to the second conductive layer via the semiconductor layer; and a control circuit configured to control the memory cell. The control circuit is capable of executing a first write operation to the memory cell. The first write operation is to apply a first voltage pulse having a first voltage with a first polarity and a first pulse width between the first wiring and the second wiring. The control circuit is capable of executing an erase operation to the memory cell. The erase operation is to apply a second voltage pulse having a second voltage with a second polarity opposite to the first polarity and a second pulse width between the first wiring and the second wiring. The control circuit is capable of executing a second write operation to the memory cell. The second write operation is to apply a third voltage pulse having a third voltage with the first polarity having a smaller absolute value than an absolute value of the first voltage and a third pulse width between the first wiring and the second wiring. The control circuit is capable of executing a first operation to the memory cell before the second write operation, the first operation being consecutive with the second write operation. The first operation is to apply a fourth voltage pulse having a fourth voltage with the first polarity having a larger absolute value than the absolute value of the third voltage and a fourth pulse width and apply a fifth voltage pulse having a fifth voltage with the second polarity having a larger absolute value than the absolute value of the third voltage and a fifth pulse width between the first wiring and the second wiring, the applying of the fifth voltage pulse being consecutive with the applying of the fourth voltage pulse.

The semiconductor memory device of the fifth embodiment is different from the semiconductor memory device of the first embodiment in that a ferroelectric random access memory (FeRAM) using a ferroelectric capacitor is included instead of the two-dimensional NOR memory. Hereinafter, description of contents overlapping with the first embodiment may be partially omitted.

The semiconductor memory device of the fifth embodiment includes a FeRAM using a ferroelectric capacitor. The semiconductor memory device of the fifth embodiment uses, as the memory cell, a capacitor containing a ferroelectric in a capacitor insulating layer. The semiconductor memory device of the fifth embodiment is a multi-level memory in which one memory cell can hold three or more levels.

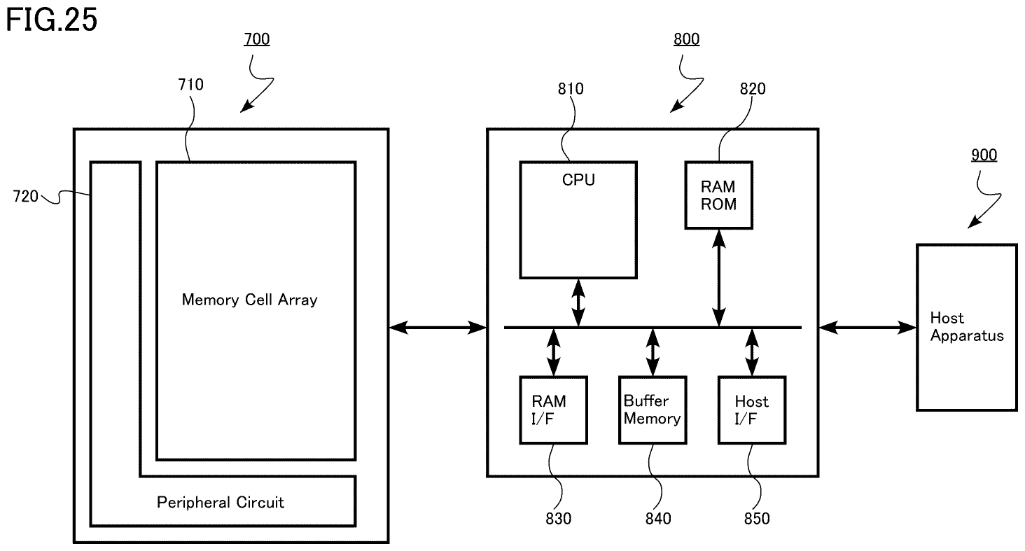

FIG. 25 is a block diagram of a memory system including a semiconductor memory device of a fifth embodiment. The memory system of the fifth embodiment includes, for example, a FeRAM 700, a controller 800, and a host apparatus 900. The semiconductor memory device of the fifth embodiment includes, for example, the FeRAM 700 and the controller 800.

The FeRAM 700 is, for example, a FeRAM chip. The controller 800 is, for example, a controller chip.

The FeRAM 700 and the controller 800 may be provided in the same semiconductor chip, for example.

The host apparatus 900 is, for example, a personal computer.

As illustrated in FIG. 25, the FeRAM 700 includes a memory cell array 710 and a peripheral circuit 720.

The controller 800 controls the FeRAM 700. The controller 800 accesses the FeRAM 700 in response to an instruction received from the host apparatus 900.

The peripheral circuit 720 of the FeRAM 700 and the controller 200 control, for example, writing of data to a memory cell included in the memory cell array 710, reading of data from the memory cell, or erasing data in the memory cell. The peripheral circuit 720 of the FeRAM 700 and the controller 800 are examples of the control circuit of the fifth embodiment.

As illustrated in FIG. 25, the controller 800 includes a processor 810 (CPU), a built-in memory 820 (RAM, ROM), a RAM interface circuit 830, a buffer memory 840, and a host interface circuit 850.

The processor 810 controls the overall operation of the controller 800. The processor 810 has a function of executing various processes for managing the FeRAM 700.

The built-in memory 820 is, for example, a semiconductor memory. The built-in memory 820 is used, for example, as a work area for the processor. The built-in memory 820 stores, for example, firmware for managing the FeRAM 700 and various management tables.

The RAM interface circuit 830 is connected to the FeRAM 700 via a RAM bus. The RAM interface circuit 830 has a function of controlling communication with the FeRAM 700.

The buffer memory 840 has, for example, a function of temporarily storing data written into memory cells or data read from memory cells.

The host interface circuit 850 is connected to the host apparatus 900 via a host bus. The host interface circuit 850 transmits, for example, an instruction received from the host apparatus 900 to the processor 810. The host interface circuit 850 transmits, for example, data received from the host apparatus 900 to the buffer memory 840. The host interface circuit 850 transmits, for example, data in the buffer memory 840 to the host apparatus 900 in response to an instruction from the processor 810.

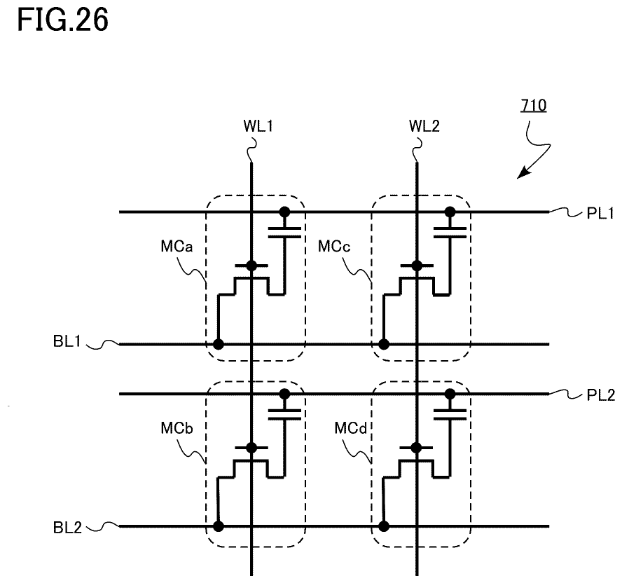

FIG. 26 is an equivalent circuit diagram of a part of a memory cell array of the semiconductor memory device of the fifth embodiment. FIG. 26 is an equivalent circuit diagram of a part of the memory cell array 710 of the FeRAM 700.

As illustrated in FIG. 26, the memory cell array 710 includes a plurality of memory cells MC, a plurality of word lines WL, a plurality of bit lines BL, and a plurality of plate lines PL. The plurality of memory cells MC include a memory cell MCa, a memory cell MCb, a memory cell MCc, and a memory cell MCd. The plurality of word lines WL include a first word line WL1 and a second word line WL2. The plurality of bit lines BL includes a first bit line BL1 and a second bit line BL2. The plurality of plate lines PL include a first plate line PL1 and a second plate line PL2.

The plurality of word lines WL are arranged in parallel so as to be spaced from each other. The plurality of bit lines BL cross the word lines WL, for example. The plurality of bit lines BL are arranged in parallel so as to be spaced from each other. The plurality of plate lines PL cross the word lines WL, for example. The plurality of plate lines PL are arranged in parallel so as to be spaced from each other.

By selecting one plate line PL, one bit line BL, and one word line WL, one memory cell MC can be selected.

The memory cell MC includes one transistor and one capacitor. The capacitor is a ferroelectric capacitor using a ferroelectric as a capacitor insulating layer. The word line WL is a gate electrode of a transistor constituting the memory cell MC. The transistor is a field effect transistor whose operation is controlled by a voltage applied to its gate electrode. Writing of data stored in the capacitor and reading of data stored in the capacitor are performed using the transistor as a switching element.

The FeRAM 700 is configured to allow random access to the plurality of memory cells MC included in the memory cell array 710.

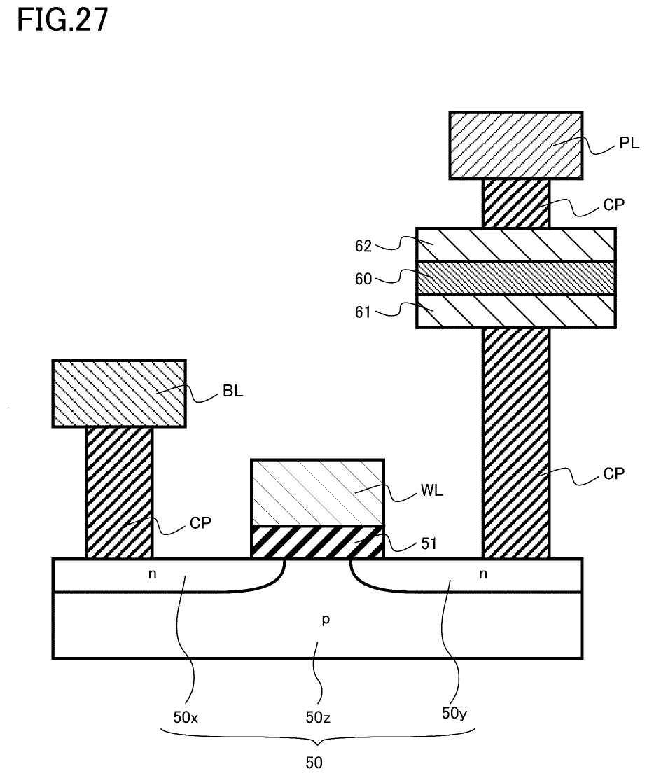

FIG. 27 is a schematic cross-sectional view including a memory cell of the semiconductor memory device of the fifth embodiment.

As illustrated in FIG. 27, the memory cell MC includes a semiconductor layer 50, a word line WL, a gate insulating layer 51, contact plugs CP, a capacitor insulating layer 60, a first capacitor electrode 61, and a second capacitor electrode 62. The semiconductor layer 50 includes a source region 50x, a drain region 50y, and a channel region 50z. The bit line BL and the plate line PL are connected to the memory cell MC.

The word line WL is an example of the gate electrode layer. The first capacitor electrode 61 is an example of the first conductive layer. The second capacitor electrode 62 is an example of the second conductive layer. The bit line BL is an example of the first wiring. The plate line PL is an example of the second wiring.

The semiconductor layer 50 is, for example, single crystal silicon. The source region 50x and the drain region 50y are, for example, n-type semiconductors. The channel region 10z is, for example, a p-type semiconductor.

The word line WL is a conductor. The word line WL is, for example, a metal. The contact plug CP is a conductor. The contact plug CP is, for example, a metal.

The gate insulating layer 51 contains a paraelectric. The gate insulating layer 51 is, for example, silicon oxide.

The capacitor insulating layer 60 is provided between the first capacitor electrode 61 and the second capacitor electrode 62. The capacitor insulating layer 60 contains a ferroelectric. The capacitor insulating layer 60 is, for example, a ferroelectric layer.

The capacitor insulating layer 60 contains, for example, at least one element selected from the group consisting of hafnium (Hf) and zirconium (Zr), and oxygen.

The capacitor insulating layer 60 is, for example, polycrystalline. The gate insulating layer 11 contains, for example, a crystal having one space group selected from the group consisting of a space group Pca21 (space group number 29), a space group R3 (space group number 146), a space group R3m (space group number 160), and Pmn21 (space group number 31). An oxide of hafnium (Hf) or zirconium (Zr) having a space group Pca21 (space group number 29), space group R3 (space group number 146), space group R3m (space group number 160), or Pmn21 (space group number 31) is a ferroelectric.

The first capacitor electrode 61 is electrically connected to the semiconductor layer 50 by using the contact plug CP. The first capacitor electrode 61 is electrically connected to the drain region 50y.

The bit line BL is electrically connected to the semiconductor layer 50 by using the contact plug CP. The bit line BL is electrically connected to the source region 50x. The bit line BL is electrically connected to the first capacitor electrode 61 via the semiconductor layer 50. The bit line BL is electrically connected to the first capacitor electrode 61 when the transistor of the memory cell MC is turned on.

The plate line PL is electrically connected to the second capacitor electrode 62 by using the contact plug CP.

Data corresponding to the polarization amount of the ferroelectric included in the capacitor insulating layer 60 is stored in the memory cell MC of the FeRAM 700. A possible level of the memory cell MC of the semiconductor memory device of the fifth embodiment is the same as in the first embodiment described with reference to FIG. 4. In the fifth embodiment, the ferroelectric is contained in the capacitor insulating layer instead of the gate insulating layer as in the first embodiment, but the problem of a write failure or an erase failure may occur due to the imprinting of the ferroelectric is common to the first embodiment.

The peripheral circuit 720 and the controller 800 are capable of executing the first write operation, the erase operation, the second write operation, and the suppression operation consecutive with the second write operation before the second write operation to any one memory cell MC selected from the memory cells MCa to MCd, for example. The voltage pulses applied to the memory cell MC in the first write operation, the erase operation, the second write operation, and the suppression operation in the control of the semiconductor memory device of the fifth embodiment are the same as in the semiconductor memory device of the first embodiment. The suppression operation is an example of the first operation.

For example, when the first write operation, the erase operation, the second write operation, and the suppression operation are performed on the memory cell MCa, the first bit line BL1 is an example of the first wiring and the first plate line PL1 is an example of the second wiring. Hereinafter, a case where the first write operation, the erase operation, the second write operation, and the suppression operation are performed on the memory cell MCa will be described as an example.

The first write operation is to apply the first write voltage pulse WP1 between the first bit line BL1 and the first plate line PL1. At this time, for example, the first word line WL1 is controlled to turn on the transistor. The first write operation is to apply the first write voltage pulse WP1 to the capacitor insulating layer 60 of the memory cell MCa.

The first write voltage pulse WP1 has a first write voltage Vwrite1 with a first polarity and a first pulse width w1. The first write voltage pulse WP1 is an example of the first voltage pulse. The first write voltage Vwrite1 is an example of the first voltage.

The erase operation is to apply the erase voltage pulse EP between the first bit line BL1 and the first plate line PL1. At this time, for example, the first word line WL1 is controlled to turn on the transistor. The erase operation is to apply the erase voltage pulse EP to the capacitor insulating layer 60 of the memory cell MCa.

The erase voltage pulse EP has an erase voltage Verase with a second polarity opposite to the first polarity and a second pulse width w2. The erase voltage pulse EP is an example of the second voltage pulse. The erase voltage Verase is an example of the second voltage.

The second write operation is to apply the second write voltage pulse WP2 between the first bit line BL1 and the first plate line PL1. At this time, for example, the first word line WL1 is controlled to turn on the transistor. The second write operation is to apply the second write voltage pulse WP2 to the capacitor insulating layer 60 of the memory cell MCa.

The second write voltage pulse WP2 has a second write voltage Vwrite2 with the first polarity and a third pulse width w3. The second write voltage pulse WP2 is an example of the third voltage pulse. The second write voltage Vwrite2 is an example of the third voltage.

The suppression operation is to apply the first suppression voltage pulse SP1 and the second suppression voltage pulse SP2 between the first bit line BL1 and the first plate line PL1. The suppression operation is to apply the first suppression voltage pulse SP1 and the second suppression voltage pulse SP2 to the capacitor insulating layer 60 of the memory cell MCa.

The first suppression voltage pulse SP1 has a first suppression voltage Vsup1 with the first polarity and a fourth pulse width w4. The first suppression voltage pulse SP1 is an example of the fourth voltage pulse. The first suppression voltage Vsup1 is an example of the fourth voltage.

The second suppression voltage pulse SP2 has a second suppression voltage Vsup2 with the second polarity and a fifth pulse width w5. The second suppression voltage pulse SP2 is an example of the fifth voltage pulse. The second suppression voltage Vsup2 is an example of the fifth voltage.

For example, the first polarity is a polarity in which the first plate line PL1 has a positive voltage with respect to the first bit line BL1, and the second polarity is a polarity in which the first plate line PL1 has a negative voltage with respect to the first bit line BL1.

Similarly to the semiconductor memory device of the first embodiment, the semiconductor memory device of the fifth embodiment can cause polarization inversion in all polarization domains of the memory cell MC by performing the suppression operation before the second write operation. Therefore, imprinting of the memory cell MC is suppressed, and a write failure or an erase failure of the memory cell MC is suppressed. Therefore, a semiconductor memory device having excellent characteristics including the three-dimensional NAND flash memory 400 can be realized.

### Modification

A modification of the semiconductor memory device of the fifth embodiment is different from the semiconductor memory device of the fifth embodiment in that the second write operation is to apply a third voltage pulse having a third voltage with the second polarity having a smaller absolute value than an absolute value of the second voltage and a third pulse width between the first wiring and the second wiring, and the first operation is to apply a fourth voltage pulse having a fourth voltage with the second polarity having a larger absolute value than the absolute value of the third voltage and a fourth pulse width and apply a fifth voltage pulse having a fifth voltage with the first polarity having a larger absolute value than the absolute value of the third voltage and a fifth pulse width between the first wiring and the second wiring, the applying of the fifth voltage pulse being consecutive with the applying of the fourth voltage pulse.

A possible level of the memory cell MC of the modification of the semiconductor memory device of the fifth embodiment is the same as in the modification of the first embodiment described with reference to FIG. 8. The voltage pulses applied to the memory cell MC in the first write operation, the erase operation, the second write operation, and the suppression operation in the control of the modification of the semiconductor memory device of the fifth embodiment are the same as in the modification of the semiconductor memory device of the first embodiment.

Similarly to the modification of the semiconductor memory device of the first embodiment, the modification of the semiconductor memory device of the fifth embodiment can cause polarization inversion in all polarization domains of the memory cell MC by performing the suppression operation before the second write operation. Therefore, imprinting of the memory cell MC is suppressed, and a write failure or an erase failure of the memory cell MC is suppressed. Therefore, a semiconductor memory device having excellent characteristics including the three-dimensional NAND flash memory 400 can be realized.

As described above, according to the fifth embodiment and the modification, imprinting of a memory cell is suppressed, and a semiconductor memory device having excellent characteristics can be realized.

### Sixth Embodiment

A semiconductor memory device of a sixth embodiment includes: a memory cell including a semiconductor layer, a gate electrode layer, a gate insulating layer provided between the semiconductor layer and the gate electrode layer, a first conductive layer electrically connected to the semiconductor layer, a second conductive layer, and a capacitor insulating layer containing a ferroelectric and provided between the first conductive layer and the second conductive layer; a first wiring electrically connected to the first conductive layer via the semiconductor layer and a second wiring electrically connected to the second conductive layer via the semiconductor layer; and a control circuit configured to control the memory cell. The control circuit is capable of executing a first write operation to the memory cell. The first write operation is to apply a first voltage pulse having a first voltage with a first polarity and a first pulse width between the first wiring and the second wiring. The control circuit is capable of executing an erase operation to the memory cell. The erase operation is to apply a second voltage pulse having a second voltage with a second polarity opposite to the first polarity and a second pulse width between the first wiring and the second wiring. The control circuit is capable of executing a second write operation to the memory cell. The second write operation is to apply a third voltage pulse having a third voltage with the first polarity having a smaller absolute value than an absolute value of the first voltage and a third pulse width between the first wiring and the second wiring. The control circuit is capable of determining whether or not the number of times of execution of the second write operation to the memory cell has reached a predetermined first number of times. The control circuit is capable of executing a first operation to the memory cell when it is determined that the number of times of execution has reached the predetermined first number of times. The first operation is to apply a fourth voltage pulse having a fourth voltage with the first polarity having a larger absolute value than the absolute value of the third voltage and a fourth pulse width and apply a fifth voltage pulse having a fifth voltage with the second polarity having a larger absolute value than the absolute value of the third voltage and a fifth pulse width between the first wiring and the second wiring, the applying of the fifth voltage pulse being consecutive with the applying of the fourth voltage pulse.

The semiconductor memory device of the sixth embodiment is different from the semiconductor memory device of the fifth embodiment in that a recovery operation is performed. Hereinafter, description of contents overlapping with the fifth embodiment may be partially omitted.

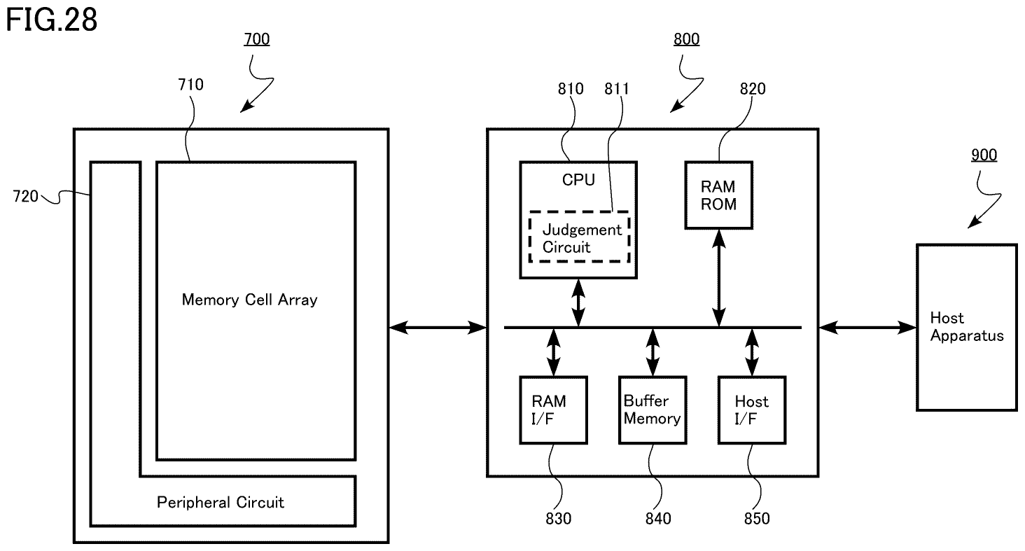

FIG. 28 is a block diagram of a memory system including a semiconductor memory device of a sixth embodiment. The memory system of the sixth embodiment includes, for example, a FeRAM 700, a controller 800, and a host apparatus 900. The semiconductor memory device of the fifth embodiment includes, for example, the FeRAM 700 and the controller 800.

The peripheral circuit 720 of the FeRAM 700 and the controller 800 are examples of the control circuit of the sixth embodiment.

The processor 810 of the sixth embodiment includes a judgement circuit 811 unlike the processor 810 of the fifth embodiment.

The built-in memory 820 stores, for example, the number of times of execution of the second write operation executed to each of the memory cells included in the FeRAM 700. The built-in memory 820 stores, for example, a predetermined first number of times of the second write operation serving as a criterion for determining whether or not to execute the recovery operation. The judgement circuit 811 is capable of determining whether or not the number of times of execution of the second write operation to a memory cell has reached the predetermined number of times on the basis of the number of times of execution of the second write operation and the predetermined first number of times of the second write operation stored in the built-in memory 820.

The peripheral circuit 720 of the FeRAM 700 and the controller 800 are capable of executing the recovery operation to a specific memory cell when it is determined that the number of times of execution of the second write operation to the specific memory cell has reached the predetermined first number of times. The recovery operation is an example of the first operation.

A possible level of the memory cell MC of the semiconductor memory device of the sixth embodiment is the same as in the first embodiment described with reference to FIG. 4.

The peripheral circuit 720 and the controller 800 are capable of executing the first write operation, the erase operation, the second write operation, and the recovery operation to any one memory cell MC selected from the memory cells MCa to MCd, for example. The first write operation, the erase operation, and the second write operation in the control of the semiconductor memory device of the sixth embodiment are the same as in the semiconductor memory device of the fifth embodiment. The voltage pulse applied to the memory cell MC in the recovery operation is the same as in the semiconductor memory device of the second embodiment.

For example, when the recovery operation is performed on the memory cell MCa, the first bit line BL1 is an example of the first wiring and the first plate line PL1 is an example of the second wiring. Hereinafter, a case where the recovery operation is performed on the memory cell MCa will be described as an example.

The recovery operation is to apply the first recovery voltage pulse RP1 and the second recovery voltage pulse RP2 between the first bit line BL1 and the first plate line PL1. The recovery operation is to apply the first recovery voltage pulse RP1 and the second recovery voltage pulse RP2 to the capacitor insulating layer 60 of the memory cell MCa.

The first recovery voltage pulse RP1 has a first recovery voltage Vrp1 with the first polarity and a fourth pulse width w4. The first recovery voltage pulse RP1 is an example of the fourth voltage pulse. The first recovery voltage Vrp1 is an example of the fourth voltage.

The second recovery voltage pulse RP2 has a second recovery voltage Vrp2 with the second polarity and a fifth pulse width w5. The second recovery voltage pulse RP2 is an example of the fifth voltage pulse. The second recovery voltage Vrp2 is an example of the fifth voltage.

For example, the first polarity is a polarity in which the first plate line PL1 has a positive voltage with respect to the first bit line BL1, and the second polarity is a polarity in which the first plate line PL1 has a negative voltage with respect to the first bit line BL1.

Similarly to the second embodiment, the semiconductor memory device of the sixth embodiment performs a recovery operation for recovering the imprinting of the memory cell MC when the second write operation for accelerating the imprinting of the memory cell MC reaches the predetermined first number of times. Therefore, imprinting of the memory cell MC is effectively recovered, and a write failure or an erase failure of the memory cell MC is suppressed. Therefore, a semiconductor memory device having excellent characteristics including the FeRAM 700 can be realized.

### Modification

A modification of the semiconductor memory device of the sixth embodiment is different from the semiconductor memory device of the sixth embodiment in that the second write operation is to apply a third voltage pulse having a third voltage with the second polarity having a smaller absolute value than an absolute value of the second voltage and a third pulse width between the first wiring and the second wiring, and the first operation is to apply a fourth voltage pulse having a fourth voltage with the second polarity having a larger absolute value than the absolute value of the third voltage and a fourth pulse width and apply a fifth voltage pulse having a fifth voltage with the first polarity having a larger absolute value than the absolute value of the third voltage and a fifth pulse width between the first wiring and the second wiring, the applying of the fifth voltage pulse being consecutive with the applying of the fourth voltage pulse.

A possible level of the memory cell MC of the modification of the semiconductor memory device of the sixth embodiment is the same as in the modification of the first embodiment described with reference to FIG. 8. The first write operation, the erase operation, and the second write operation in the control of the modification of the semiconductor memory device of the sixth embodiment are the same as in the modification of the fifth embodiment. The voltage pulse applied to the memory cell MC in the recovery operation is the same as in the modification of the semiconductor memory device of the second embodiment.

Similarly to the modification of the second embodiment, the modification of the semiconductor memory device of the sixth embodiment performs a recovery operation for recovering the imprinting of the memory cell MC when the second write operation for accelerating the imprinting of the memory cell MC reaches the predetermined first number of times. Therefore, imprinting of the memory cell MC is effectively recovered, and a write failure or an erase failure of the memory cell MC is suppressed. Therefore, a semiconductor memory device having excellent characteristics including the FeRAM 700 can be realized.

As described above, according to the sixth embodiment and the modification, imprinting of a memory cell is effectively recovered, and a semiconductor memory device having excellent characteristics can be realized. In the third and fourth embodiments, the structure in which the semiconductor layer 10 is surrounded by the word lines WL has been described as an example, but the semiconductor layer 10 may be sandwiched between the word lines WL divided into two. In the case of this structure, the number of memory cells in the stacked body 30 can be doubled.

In the third and fourth embodiments, the structure in which one semiconductor layer 10 is provided in one memory hole has been described as an example, but a structure in which a plurality of semiconductor layers 10 divided into two or more is provided in one memory hole can also be adopted. In the case of this structure, the number of memory cells in the stacked body 30 can be set to be equal to or more than twice.

In the third and fourth embodiments, the NAND flash memory having a three-dimensional structure has been described as an example, but the NAND flash memory may have a two-dimensional structure.

The two-dimensional NOR memory in the first and second embodiments, the three-dimensional NAND flash memory in the third and fourth embodiments, and the FeRAM using a ferroelectric capacitor in the fifth and sixth embodiments have been described as examples, but the disclosure can also be applied to other semiconductor memory devices using an insulating layer containing a ferroelectric for a memory cell.

In the first to sixth embodiments, the positive and negative directions of the first polarity and the second polarity can be reversed.

In the first to sixth embodiments, a case where there is one intermediate state has been described as an example, but for example, it is also possible to have a form in which there are a plurality of different intermediate states and there are four or more memory cells.

While certain embodiments have been described, these embodiments have been presented by way of example only, and are not intended to limit the scope of the inventions. Indeed, the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

Embodiments of the disclosure include the following technical ideas.

### Technical Idea 1

A semiconductor memory device including:
a memory cell including a semiconductor layer, a gate electrode layer, and a gate insulating layer containing a ferroelectric and provided between the semiconductor layer and the gate electrode layer;
a first wiring and a second wiring electrically connected to the semiconductor layer; and
a control circuit configured to control the memory cell,
wherein the control circuit is configured to execute a first write operation to the memory cell, and in the first write operation, a first voltage pulse having a first voltage with a first polarity and a first pulse width is applied between the gate electrode layer and at least one of the first wiring and the second wiring,
the control circuit is configured to execute an erase operation to the memory cell, and in the erase operation, a second voltage pulse having a second voltage with a second polarity opposite to the first polarity and a second pulse width is applied between the gate electrode layer and at least one of the first wiring and the second wiring,
the control circuit is configured to execute a second write operation to the memory cell, and in the second write operation, a third voltage pulse having a third voltage with the second polarity having a smaller absolute value than an absolute value of the second voltage and a third pulse width is applied between the gate electrode layer and at least one of the first wiring and the second wiring, and
the control circuit is configured to execute a first operation to the memory cell before the second write operation, the first operation is consecutive with the second write operation, and
in the first operation, a fourth voltage pulse having a fourth voltage with the second polarity having a larger absolute value than the absolute value of the third voltage and a fourth pulse width and a fifth voltage pulse having a fifth voltage with the first polarity having a larger absolute value than the absolute value of the third voltage and a fifth pulse width are applied between the gate electrode layer and at least one of the first wiring and the second wiring, and the fifth voltage pulse is applied consecutively after the fourth voltage pulse is applied.

### Technical Idea 2

The semiconductor memory device according to Technical idea 1, wherein the absolute value of the fourth voltage is equal to or more than the absolute value of the second voltage, and the absolute value of the fifth voltage is equal to or more than an absolute value of the first voltage.

### Technical Idea 3

The semiconductor memory device according to Technical idea 1, wherein the fourth pulse width is equal to or more than the third pulse width, and the fifth pulse width is equal to or more than the third pulse width.

### Technical Idea 4

The semiconductor memory device according to Technical idea 1, wherein the gate insulating layer contains at least one element selected from the group consisting of hafnium (Hf) and zirconium (Zr), and oxygen.

### Technical Idea 5

The semiconductor memory device according to Technical idea 4, wherein the gate insulating layer contains a crystal having one space group selected from the group consisting of a space group Pca21 (space group number 29), a space group R3 (space group number 146), a space group R3m (space group number 160), and Pmn21 (space group number 31).

### Technical Idea 6

A semiconductor memory device comprising:
a memory cell including a semiconductor layer, a gate electrode layer, and a gate insulating layer containing a ferroelectric and provided between the semiconductor layer and the gate electrode layer;
a first wiring and a second wiring electrically connected to the semiconductor layer; and
a control circuit configured to control the memory cell,
wherein the control circuit is configured to execute a first write operation to the memory cell, and in the first write operation, a first voltage pulse having a first voltage with a first polarity and a first pulse width is applied between the gate electrode layer and at least one of the first wiring and the second wiring,
the control circuit is configured to execute an erase operation to the memory cell, and in the erase operation, a second voltage pulse having a second voltage with a second polarity opposite to the first polarity and a second pulse width is applied between the gate electrode layer and at least one of the first wiring and the second wiring,
the control circuit is configured to execute a second write operation to the memory cell, and in the second write operation, a third voltage pulse having a third voltage with the second polarity having a smaller absolute value than an absolute value of the second voltage and a third pulse width is applied between the gate electrode layer and at least one of the first wiring and the second wiring,
the control circuit is configured to determine whether or not number of times of execution of the second write operation to the memory cell has reached a predetermined first number of times, and
the control circuit is configured to execute a first operation to the memory cell when it is determined that the number of times of execution has reached the predetermined first number of times, and
in the first operation, a fourth voltage pulse having a fourth voltage with the second polarity having a larger absolute value than the absolute value of the third voltage and a fourth pulse width and a fifth voltage pulse having a fifth voltage with the first polarity having a larger absolute value than the absolute value of the third voltage and a fifth pulse width are applied between the gate electrode layer and at least one of the first wiring and the second wiring, and the fifth voltage pulse is applied consecutively after the fourth voltage pulse is applied.

### Technical Idea 7

The semiconductor memory device according to Technical idea 6, wherein the absolute value of the fourth voltage is equal to or more than the absolute value of the second voltage, and the absolute value of the fifth voltage is equal to or more than an absolute value of the first voltage.

### Technical Idea 8

The semiconductor memory device according to Technical idea 6, wherein the fourth pulse width is equal to or more than the third pulse width, and the fifth pulse width is equal to or more than the third pulse width.

### Technical Idea 9

The semiconductor memory device according to Technical idea 6, wherein the control circuit is configured to consecutively execute the first operation a plurality of times.

### Technical Idea 10

The semiconductor memory device according to Technical idea 6, wherein the control circuit is configured to determine whether or not the number of times of consecutive execution of the second write operation to the memory cell has reached the predetermined first number of times.

### Technical Idea 11

The semiconductor memory device according to Technical idea 6, wherein the gate insulating layer contains at least one element selected from the group consisting of hafnium (Hf) and zirconium (Zr), and oxygen.

### Technical Idea 12

The semiconductor memory device according to Technical idea 11, wherein the gate insulating layer contains a crystal having one space group selected from the group consisting of a space group Pca21 (space group number 29), a space group R3 (space group number 146), a space group R3m (space group number 160), and Pmn21 (space group number 31).

### Technical Idea 13

A semiconductor memory device including:
a memory cell array including
a first semiconductor layer extending in a first direction,
a plurality of gate electrode layers stacked in the first direction,
a first wiring electrically connected to the first semiconductor layer,
a second wiring electrically connected to the first semiconductor layer, and
a plurality of first memory cells, each of the first memory cells including the first semiconductor layer, one gate electrode layer of the gate electrode layers, and a gate insulating layer containing a ferroelectric and provided between the first semiconductor layer and the one gate electrode layer; and
a control circuit configured to control the first memory cells,
wherein the control circuit is configured to execute a first write operation to one first memory cell selected from the first memory cells, and in the first write operation, a first voltage pulse having a first voltage with a first polarity and a first pulse width is applied between the one gate electrode layer of the one first memory cell and at least one of the first wiring and the second wiring,
the control circuit is configured to execute an erase operation to the one first memory cell, and in the erase operation, a second voltage pulse having a second voltage with a second polarity opposite to the first polarity and a second pulse width is applied between the one gate electrode layer of the one first memory cell and at least one of the first wiring and the second wiring,
the control circuit is configured to execute a second write operation to the one first memory cell, and in the second write operation, a third voltage pulse having a third voltage with the second polarity having a smaller absolute value than an absolute value of the second voltage and a third pulse width is applied between the one gate electrode layer of the one first memory cell and at least one of the first wiring and the second wiring, and
the control circuit is configured to execute a first operation to the one first memory cell before the second write operation, the first operation is consecutive with the second write operation, and
in the first operation, a fourth voltage pulse having a fourth voltage with the second polarity having a larger absolute value than the absolute value of the third voltage and a fourth pulse width and a fifth voltage pulse having a fifth voltage with the first polarity having a larger absolute value than the absolute value of the third voltage and a fifth pulse width are applied between the one gate electrode layer of the one first memory cell and at least one of the first wiring and the second wiring in the second write operation, and the fifth voltage pulse is consecutively applied after the fourth voltage pulse is applied.

### Technical Idea 14

The semiconductor memory device according to technical idea 13, wherein the absolute value of the fourth voltage is equal to or more than the absolute value of the second voltage, and the absolute value of the fifth voltage is equal to or more than an absolute value of the first voltage.

### Technical Idea 15

A semiconductor memory device including:
a memory cell array including
a first semiconductor layer extending in a first direction,
a second semiconductor layer extending in the first direction,
a plurality of gate electrode layers stacked in the first direction,
a first wiring electrically connected to the first semiconductor layer and the second semiconductor layer,
a second wiring electrically connected to the first semiconductor layer,
a third wiring electrically connected to the second semiconductor layer,
a plurality of first memory cells, each of the first memory cells including the first semiconductor layer, one gate electrode layer of the gate electrode layers, and a gate insulating layer containing a ferroelectric and provided between the first semiconductor layer and the one gate electrode layer, and
a plurality of second memory cells, each of the second memory cells including the second semiconductor layer, one gate electrode layer of the gate electrode layers, and a gate insulating layer containing a ferroelectric and provided between the second semiconductor layer and the one gate electrode layer; and
a control circuit configured to control the first memory cells and the second memory cells,
wherein the control circuit is configured to execute a first write operation to any one memory cell of the first memory cells and the second memory cells, and in the first write operation, a first voltage pulse having a first voltage with a first polarity and a first pulse width is applied between one gate electrode layer of the one memory cell and at least one of the first wiring and the second wiring when the one memory cell is one of the first memory cells, or in the first write operation, the first voltage pulse having a first voltage with a first polarity and a first pulse width is applied between one gate electrode layer of the one memory cell and at least one of the first wiring and the third wiring when the one memory cell is one of the second memory cells,
the control circuit is configured to execute an erase operation to the first memory cells and the second memory cells, and in the erase operation, a second voltage pulse having a second voltage with a second polarity opposite to the first polarity and a second pulse width is applied between gate electrode layers and the first wiring,
the control circuit is configured to execute a second write operation to the one memory cell, and in the second write operation, a third voltage pulse having a third voltage with the second polarity having a smaller absolute value than an absolute value of the second voltage and a third pulse width is applied between the one gate electrode layer of the one memory cell and at least one of the first wiring and the second wiring when the one memory cell is one of the first memory cells, or in the second write operation, the third voltage pulse having a third voltage with the second polarity having a smaller absolute value than an absolute value of the second voltage and a third pulse width is applied between the one gate electrode layer of the one memory cell and at least one of the first wiring and the third wiring when the one memory cell is one of the second memory cells,
the control circuit is configured to determine whether or not number of times of execution of the second write operation to each of the first memory cells and the second memory cells has reached a predetermined first number of times, and
the control circuit is configured to execute a first operation to the first memory cells and the second memory cells when it is determined that the number of times of execution to any of the first memory cells and the second memory cells has reached the predetermined first number of times, and
in the first operation, a fourth voltage pulse having a fourth voltage with the second polarity having a larger absolute value than the absolute value of the third voltage and a fourth pulse width and a fifth voltage pulse having a fifth voltage with the first polarity having a larger absolute value than the absolute value of the third voltage and a fifth pulse width are applied between the gate electrode layers and the first wiring, and the fifth voltage pulse is applied consecutive after the fourth voltage pulse is applied.

### Technical Idea 16

The semiconductor memory device according to technical idea 15, wherein the absolute value of the fourth voltage is equal to or more than the absolute value of the second voltage, and the absolute value of the fifth voltage is equal to or more than an absolute value of the first voltage.

### Technical Idea 17

A semiconductor memory device including:
a memory cell including a semiconductor layer, a gate electrode layer, a gate insulating layer provided between the semiconductor layer and the gate electrode layer, a first conductive layer electrically connected to the semiconductor layer, a second conductive layer, and a capacitor insulating layer containing a ferroelectric and provided between the first conductive layer and the second conductive layer;
a first wiring electrically connected to the first conductive layer via the semiconductor layer and a second wiring electrically connected to the second conductive layer; and
a control circuit configured to control the memory cell,
wherein the control circuit configured to execute a first write operation to the memory cell, and in the first write operation, a first voltage pulse having a first voltage with a first polarity and a first pulse width is applied between the first wiring and the second wiring,
the control circuit is configured to execute an erase operation to the memory cell, and in the erase operation, a second voltage pulse having a second voltage with a second polarity opposite to the first polarity and a second pulse width is applied between the first wiring and the second wiring,
the control circuit is configured to execute a second write operation to the memory cell, and in the second write operation, a third voltage pulse having a third voltage with the second polarity having a smaller absolute value than an absolute value of the second voltage and a third pulse width is applied between the first wiring and the second wiring, and
the control circuit is configured to execute a first operation to the memory cell before the second write operation, the first operation is consecutive with the second write operation, and
in the first operation, a fourth voltage pulse having a fourth voltage with the second polarity having a larger absolute value than the absolute value of the third voltage and a fourth pulse width and a fifth voltage pulse having a fifth voltage with the first polarity having a larger absolute value than the absolute value of the third voltage and a fifth pulse width are applied between the first wiring and the second wiring, and the fifth voltage pulse is consecutively applied after the fourth voltage pulse is applied.

### Technical Idea 18

The semiconductor memory device according to technical idea 17, wherein the absolute value of the fourth voltage is equal to or more than the absolute value of the second voltage, and the absolute value of the fifth voltage is equal to or more than an absolute value of the first voltage.

### Technical Idea 19

A semiconductor memory device including:
a memory cell including a semiconductor layer, a gate electrode layer, a gate insulating layer provided between the semiconductor layer and the gate electrode layer, a first conductive layer electrically connected to the semiconductor layer, a second conductive layer, and a capacitor insulating layer containing a ferroelectric and provided between the first conductive layer and the second conductive layer;
a first wiring electrically connected to the first conductive layer via the semiconductor layer and a second wiring electrically connected to the second conductive layer; and
a control circuit configured to control the memory cell,
wherein the control circuit is configured to execute a first write operation to the memory cell, and in the first write operation, a first voltage pulse having a first voltage with a first polarity and a first pulse width is applied between the first wiring and the second wiring,
the control circuit is configured to execute an erase operation to the memory cell, and in the erase operation, a second voltage pulse having a second voltage with a second polarity opposite to the first polarity and a second pulse width is applied between the first wiring and the second wiring,
the control circuit is configured to execute a second write operation to the memory cell, and in the second write operation, a third voltage pulse having a third voltage with the second polarity having a smaller absolute value than an absolute value of the second voltage and a third pulse width is applied between the first wiring and the second wiring,
the control circuit is configured to determine whether or not number of times of execution of the second write operation to the memory cell has reached a predetermined first number of times, and
the control circuit is configured to execute a first operation to the memory cell when it is determined that the number of times of execution has reached the predetermined first number of times, and
in the first operation, a fourth voltage pulse having a fourth voltage with the second polarity having a larger absolute value than the absolute value of the third voltage and a fourth pulse width and a fifth voltage pulse having a fifth voltage with the first polarity having a larger absolute value than the absolute value of the third voltage and a fifth pulse width are applied between the first wiring and the second wiring, and the fifth voltage pulse is consecutively applied after the fourth voltage pulse is applied.

### Technical Idea 20

The semiconductor memory device according to technical idea 19, wherein the absolute value of the fourth voltage is equal to or more than the absolute value of the second voltage, and the absolute value of the fifth voltage is equal to or more than an absolute value of the first voltage.

What is claimed is:

1. A semiconductor memory device comprising:
a memory cell including a semiconductor layer, a gate electrode layer, and a gate insulating layer containing a ferroelectric and provided between the semiconductor layer and the gate electrode layer;
a first wiring and a second wiring electrically connected to the semiconductor layer; and
a control circuit configured to control the memory cell,
wherein the control circuit is configured to execute a first write operation to the memory cell, and in the first write operation, a first voltage pulse having a first voltage with a first polarity and a first pulse width is applied between the gate electrode layer and at least one of the first wiring and the second wiring,
the control circuit is configured to execute an erase operation to the memory cell, and in the erase operation, a second voltage pulse having a second voltage with a second polarity opposite to the first polarity and a second pulse width is applied between the gate electrode layer and at least one of the first wiring and the second wiring,
the control circuit is configured to execute a second write operation to the memory cell, and in the second write operation, a third voltage pulse having a third voltage with the first polarity having a smaller absolute value than an absolute value of the first voltage and a third pulse width is applied between the gate electrode layer and at least one of the first wiring and the second wiring, and
the control circuit is configured to execute a first operation to the memory cell before the second write operation, the first operation is consecutive with the second write operation, and
in the first operation, a fourth voltage pulse having a fourth voltage with the first polarity having a larger absolute value than the absolute value of the third voltage and a fourth pulse width and a fifth voltage pulse having a fifth voltage with the second polarity having a larger absolute value than the absolute value of the third voltage and a fifth pulse width are applied between the gate electrode layer and at least one of the first wiring and the second wiring, and the fifth voltage pulse is applied consecutively after the fourth voltage pulse is applied.

2. The semiconductor memory device according to claim 1, wherein the absolute value of the fourth voltage is equal to or more than the absolute value of the first voltage, and the absolute value of the fifth voltage is equal to or more than an absolute value of the second voltage.

3. The semiconductor memory device according to claim 1, wherein the fourth pulse width is equal to or more than the third pulse width, and the fifth pulse width is equal to or more than the third pulse width.

4. The semiconductor memory device according to claim 1, wherein the gate insulating layer contains oxygen and at least one element selected from the group consisting of hafnium (Hf) and zirconium (Zr).

5. The semiconductor memory device according to claim 4, wherein the gate insulating layer contains a crystal having one space group selected from the group consisting of a space group Pca21 (space group number 29), a space group R3 (space group number 146), a space group R3m (space group number 160), and a space group Pmn21 (space group number 31).

6. A semiconductor memory device comprising:
a memory cell including a semiconductor layer, a gate electrode layer, and a gate insulating layer containing a ferroelectric and provided between the semiconductor layer and the gate electrode layer;
a first wiring and a second wiring electrically connected to the semiconductor layer; and
a control circuit configured to control the memory cell,
wherein the control circuit is configured to execute a first write operation to the memory cell, and in the first write operation, a first voltage pulse having a first voltage with a first polarity and a first pulse width is applied between the gate electrode layer and at least one of the first wiring and the second wiring,
the control circuit is configured to execute an erase operation to the memory cell, and in the erase operation, a second voltage pulse having a second voltage with a second polarity opposite to the first polarity and a second pulse width is applied between the gate electrode layer and at least one of the first wiring and the second wiring,
the control circuit is configured to execute a second write operation to the memory cell, and in the second write operation, a third voltage pulse having a third voltage with the first polarity having a smaller absolute value than an absolute value of the first voltage and a third pulse width is applied between the gate electrode layer and at least one of the first wiring and the second wiring,
the control circuit is configured to determine whether or not number of times of execution of the second write operation to the memory cell has reached a predetermined first number of times, and
the control circuit is configured to execute a first operation to the memory cell when it is determined that the number of times of execution has reached the predetermined first number of times, and
in the first operation, a fourth voltage pulse having a fourth voltage with the first polarity having a larger absolute value than the absolute value of the third voltage and a fourth pulse width and a fifth voltage pulse having a fifth voltage with the second polarity having a larger absolute value than the absolute value of the third voltage and a fifth pulse width are applied between the gate electrode layer and at least one of the first wiring and the second wiring, and the fifth voltage pulse is applied consecutively after the fourth voltage pulse is applied.

7. The semiconductor memory device according to claim 6, wherein the absolute value of the fourth voltage is equal to or more than the absolute value of the first voltage, and the absolute value of the fifth voltage is equal to or more than an absolute value of the second voltage.

8. The semiconductor memory device according to claim 6, wherein the fourth pulse width is equal to or more than the third pulse width, and the fifth pulse width is equal to or more than the third pulse width.

9. The semiconductor memory device according to claim 6, wherein the control circuit is configured to consecutively execute the first operation a plurality of times.

10. The semiconductor memory device according to claim 6, wherein the control circuit is configured to determine whether or not the number of times of consecutive execution of the second write operation to the memory cell has reached the predetermined first number of times.

11. The semiconductor memory device according to claim 6, wherein the gate insulating layer contains oxygen and at least one element selected from the group consisting of hafnium (Hf) and zirconium (Zr).

12. The semiconductor memory device according to claim 11, wherein the gate insulating layer contains a crystal having one space group selected from the group consisting of a space group Pca21 (space group number 29), a space group R3 (space group number 146), a space group R3m (space group number 160), and a space group Pmn21 (space group number 31).

13. A semiconductor memory device comprising:
a memory cell array including
a first semiconductor layer extending in a first direction,
a plurality of gate electrode layers stacked in the first direction,
a first wiring electrically connected to the first semiconductor layer,
a second wiring electrically connected to the first semiconductor layer, and
a plurality of first memory cells, each of the first memory cells including the first semiconductor layer, one gate electrode layer of the gate electrode layers, and a gate insulating layer containing a ferroelectric and provided between the first semiconductor layer and the one gate electrode layer; and
a control circuit configured to control the first memory cells,
wherein the control circuit is configured to execute a first write operation to one first memory cell selected from the first memory cells, and in the first write operation, a first voltage pulse having a first voltage with a first polarity and a first pulse width is applied between the one gate electrode layer of the one first memory cell and at least one of the first wiring and the second wiring,
the control circuit is configured to execute an erase operation to the one first memory cell, and in the erase operation, a second voltage pulse having a second voltage with a second polarity opposite to the first polarity and a second pulse width is applied between the one gate electrode layer of the one first memory cell and at least one of the first wiring and the second wiring,
the control circuit is configured to execute a second write operation to the one first memory cell, and in the second write operation, a third voltage pulse having a third voltage with the first polarity having a smaller absolute value than an absolute value of the first voltage and a third pulse width is applied between the one gate electrode layer of the one first memory cell and at least one of the first wiring and the second wiring, and
the control circuit is configured to execute a first operation to the one first memory cell before the second write operation, the first operation is consecutive with the second write operation, and
in the first operation, a fourth voltage pulse having a fourth voltage with the first polarity having a larger absolute value than the absolute value of the third voltage and a fourth pulse width and a fifth voltage pulse having a fifth voltage with the second polarity having a larger absolute value than the absolute value of the third voltage and a fifth pulse width are applied between the one gate electrode layer of the one first memory cell and at least one of the first wiring and the second wiring, and the fifth voltage pulse is applied consecutively after the fourth voltage pulse is applied.

14. The semiconductor memory device according to claim 13, wherein the absolute value of the fourth voltage is equal to or more than the absolute value of the first voltage, and the absolute value of the fifth voltage is equal to or more than an absolute value of the second voltage.

15. A semiconductor memory device comprising:
a memory cell array including
a first semiconductor layer extending in a first direction,
a second semiconductor layer extending in the first direction,
a plurality of gate electrode layers stacked in the first direction,
a first wiring electrically connected to the first semiconductor layer and the second semiconductor layer,
a second wiring electrically connected to the first semiconductor layer,
a third wiring electrically connected to the second semiconductor layer,
a plurality of first memory cells, each of the first memory cells including the first semiconductor layer, one gate electrode layer of the gate electrode layers, and a gate insulating layer containing a ferroelectric and provided between the first semiconductor layer and the one gate electrode layer, and
a plurality of second memory cells, each of the second memory cells including the second semiconductor layer, one gate electrode layer of the gate electrode layers, and a gate insulating layer containing a ferroelectric and provided between the second semiconductor layer and the one gate electrode layer; and
a control circuit configured to control the first memory cells and the second memory cells,
wherein the control circuit is configured to execute a first write operation to any one memory cell of the first memory cells and the second memory cells, and in the first write operation, a first voltage pulse having a first voltage with a first polarity and a first pulse width is applied between one gate electrode layer of the one memory cell and at least one of the first wiring and the second wiring when the one memory cell is one of the first memory cells, or in the first write operation, the first voltage pulse having the first voltage with the first polarity and the first pulse width is applied between one gate electrode layer of the one memory cell and at least one of the first wiring and the third wiring when the one memory cell is one of the second memory cells,
the control circuit is configured to execute an erase operation to the first memory cells and the second memory cells, and in the erase operation, a second voltage pulse having a second voltage with a second polarity opposite to the first polarity and a second pulse width is applied between gate electrode layers and the first wiring,
the control circuit is configured to execute a second write operation to the one memory cell, and in the second write operation, a third voltage pulse having a third voltage with the first polarity having a smaller absolute value than an absolute value of the first voltage and a third pulse width is applied between the one gate electrode layer of the one memory cell and at least one of the first wiring and the second wiring when the one memory cell is one of the first memory cells, or in the second write operation, the third voltage pulse having the third voltage with the first polarity having a smaller absolute value than the absolute value of the first voltage and the third pulse width is applied between the one gate electrode layer of the one memory cell and at least one of the first wiring and the third wiring when the one memory cell is one of the second memory cells,
the control circuit is configured to determine whether or not number of times of execution of the second write operation to each of the first memory cells and the second memory cells has reached a predetermined first number of times, and
the control circuit is configured to execute a first operation to the first memory cells and the second memory cells when it is determined that the number of times of execution to any of the first memory cells and the second memory cells has reached the predetermined first number of times, and
in the first operation, a fourth voltage pulse having a fourth voltage with the first polarity having a larger absolute value than the absolute value of the third voltage and a fourth pulse width and a fifth voltage pulse having a fifth voltage with the second polarity having a larger absolute value than the absolute value of the third voltage and a fifth pulse width are applied between the gate electrode layers and the first wiring, and the fifth voltage pulse is applied consecutively after the fourth voltage pulse is applied.

16. The semiconductor memory device according to claim 15, wherein the absolute value of the fourth voltage is equal to or more than the absolute value of the first voltage, and the absolute value of the fifth voltage is equal to or more than an absolute value of the second voltage.

17. A semiconductor memory device comprising:
a memory cell including a semiconductor layer, a gate electrode layer, a gate insulating layer provided between the semiconductor layer and the gate electrode layer, a first conductive layer electrically connected to the semiconductor layer, a second conductive layer, and a capacitor insulating layer containing a ferroelectric and provided between the first conductive layer and the second conductive layer;
a first wiring electrically connected to the first conductive layer via the semiconductor layer and a second wiring electrically connected to the second conductive layer; and
a control circuit configured to control the memory cell,
wherein the control circuit is configured to execute a first write operation to the memory cell, and in the first write operation, a first voltage pulse having a first voltage with a first polarity and a first pulse width is applied between the first wiring and the second wiring,
the control circuit is configured to execute an erase operation to the memory cell, and in the erase operation, a second voltage pulse having a second voltage with a second polarity opposite to the first polarity and a second pulse width is applied between the first wiring and the second wiring,
the control circuit is configured to execute a second write operation to the memory cell, and in the second write operation, a third voltage pulse having a third voltage with the first polarity having a smaller absolute value than an absolute value of the first voltage and a third pulse width is applied between the first wiring and the second wiring, and
the control circuit is configured to execute a first operation to the memory cell before the second write operation, the first operation is consecutive with the second write operation, and
in the first operation, a fourth voltage pulse having a fourth voltage with the first polarity having a larger absolute value than the absolute value of the third voltage and a fourth pulse width and a fifth voltage pulse having a fifth voltage with the second polarity having a larger absolute value than the absolute value of the third voltage and a fifth pulse width are applied between the first wiring and the second wiring, and the fifth voltage pulse is applied consecutively after the fourth voltage pulse is applied.

18. The semiconductor memory device according to claim 17, wherein the absolute value of the fourth voltage is equal to or more than the absolute value of the first voltage, and the absolute value of the fifth voltage is equal to or more than an absolute value of the second voltage.

19. A semiconductor memory device comprising:
a memory cell including a semiconductor layer, a gate electrode layer, a gate insulating layer provided between the semiconductor layer and the gate electrode layer, a first conductive layer electrically connected to the semiconductor layer, a second conductive layer, and a capacitor insulating layer containing a ferroelectric and provided between the first conductive layer and the second conductive layer;
a first wiring electrically connected to the first conductive layer via the semiconductor layer and a second wiring electrically connected to the second conductive layer; and
a control circuit configured to control the memory cell,
wherein the control circuit is configured to execute a first write operation to the memory cell, and in the first write operation, a first voltage pulse having a first voltage with a first polarity and a first pulse width is applied between the first wiring and the second wiring,
the control circuit is configured to execute an erase operation to the memory cell, and in the erase operation, a second voltage pulse having a second voltage with a second polarity opposite to the first polarity and a second pulse width is applied between the first wiring and the second wiring,
the control circuit is configured to execute a second write operation to the memory cell, and in the second write operation, a third voltage pulse having a third voltage with the first polarity having a smaller absolute value than an absolute value of the first voltage and a third pulse width is applied between the first wiring and the second wiring,
the control circuit is configured to determine whether or not number of times of execution of the second write operation to the memory cell has reached a predetermined first number of times, and
the control circuit is configured to execute a first operation to the memory cell when it is determined that the number of times of execution has reached the predetermined first number of times, and
in the first operation, a fourth voltage pulse having a fourth voltage with the first polarity having a larger absolute value than the absolute value of the third voltage and a fourth pulse width and a fifth voltage pulse having a fifth voltage with the second polarity having a larger absolute value than the absolute value of the third voltage and a fifth pulse width are applied between the first wiring and the second wiring, and the fifth voltage pulse is applied consecutively after the fourth voltage pulse is applied.

20. The semiconductor memory device according to claim 19, wherein the absolute value of the fourth voltage is equal to or more than the absolute value of the first voltage, and the absolute value of the fifth voltage is equal to or more than an absolute value of the second voltage.
